(19) United States
(12) Patent Application Publication
(10) Pub. No.: US 2010/0122798 A1
(43) Pub. Date: May 20, 2010

(54) HEAT TRANSPORT DEVICE, ELECTRONIC APPARATUS, AND HEAT TRANSPORT DEVICE MANUFACTURING METHOD

(75) Inventors: Mitsuo Hashimoto, Kanagawa (JP); Kazuaki Yazawa, Tokyo (JP); Yuichi Ishida, Kanagawa (JP); Hiroyuki Ryoson, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/621,204

(22) Filed: Nov. 18, 2009

(30) Foreign Application Priority Data
Nov. 20, 2008 (JP) 2008-296626

(51) Int. Cl. F28D 15/00; B05D 3/12; C23C 16/00

(52) U.S. Cl. 165/104.21; 427/356; 427/248.1

(57) ABSTRACT

According to an embodiment of the present invention, there is provided a heat transport device including an evaporation portion, a flow path, a condenser portion, and a working fluid. The evaporation portion is made of nanomaterial, and has V-shaped grooves formed on a surface. The flow path communicates with the evaporation portion. The condenser portion communicates with the evaporation portion through the flow path. The working fluid evaporates from a liquid phase to a vapor phase in the evaporation portion and condenses from the vapor phase to the liquid phase in the condenser portion.

### BACKGROUND OF THE INVENTION

1. Field of the Invention

The present invention relates to a heat transport device thermally connected to a heat source of an electronic apparatus, an electronic apparatus including the heat transport device, and a heat transport device manufacturing method.

2. Description of the Related Art

A heat transport device such as a heat spreader, a heat pipe, or a CPL (Capillary Pumped Loop) has been used as a device thermally connected to a heat source of an electronic apparatus, such as a CPU (Central Processing Unit) of a PC (Personal Computer), to absorb and diffuse heat of the heat source. For example, as the heat spreader, a solid-type metal heat spreader made of for example a copper plate is known, and a heat spreader including an evaporation portion and a working fluid has been proposed recently. Similarly, the heat pipe or the CPL includes an evaporation portion and a working fluid.

It is known that nanomaterials such as carbon nanotube are high in thermal conductivity and contribute to acceleration of evaporation. As a heat transport device using carbon nanotube as described above, a heat pipe is known (see, for example, U.S. Pat. No. 7,213,637; column 3, line 66 to column 4, line 12, FIG. 1, hereinafter referred to as Patent Document 1). The heat pipe of Patent Document 1 has a carbon nanotube layer provided on an inner wall of a pipe, and the carbon nanotube layer forms a wick.

### SUMMARY OF THE INVENTION

In general, it is known that as a surface area of an evaporation portion being in contact with a working fluid is larger, evaporation of the working fluid is accelerated. Thus, in the wick of the carbon nanotube layer of Patent Document 1, in order to improve heat diffusion efficiency, the surface area of the wick of the carbon nanotube layer only needs to be made larger. However, while an electronic apparatus mounted with such a heat transport device is required to enhance the heat radiation efficiency, the electronic apparatus itself is required to be downsized. Accordingly, in such a heat transport device, enlarging the surface area of the wick goes against the request of downsizing.

In view of the above-mentioned circumstances, it is desirable to provide a heat transport device realizing higher heat radiation efficiency without being made larger, and an electronic apparatus including the heat transport device.

It is further desirable to provide a heat transport device manufacturing method that realizes easier manufacture with higher reliability.

According to an embodiment of the present invention, there is provided a heat transport device including an evaporation portion made of nanomaterial, a flow path, a condenser portion, and a working fluid.

The evaporation portion has V-shaped grooves formed on a surface. The flow path communicates with, the evaporation portion. The condenser portion communicates with the evaporation portion through the flow path. The working fluid evaporates from a liquid phase to a vapor phase in the evaporation portion and condenses from the vapor phase to the liquid phase in the condenser portion.

According to the embodiment of the present invention, the evaporation portion is thermally connected to a heat source. The liquid-phase working fluid evaporates to be a vapor phase in the evaporation portion. The vapor-phase working fluid condenses to be the liquid phase in the condenser portion. The phase transition is repeatedly performed in the heat transport device. Because the evaporation portion has the grooves on the surface, the area of the surface' that contacts the working fluid is increased compared to an evaporation portion which is subjected to no surface processing. The liquid-phase working fluid flows in the grooves with a capillary force, with the result that the working fluid is spread over the entire grooves.

The evaporation portion is made of nanomaterial, for example, carbon nanotube. The carbon nanotube has approximately 10 times higher thermal conductivity than copper, a typical metal material of a metal heat spreader, for example. Accordingly, by providing the evaporation portion made of carbon nanotube, extremely improved heat transfer efficiency is obtained compared to a heat transport device mainly made of a metal material.

The evaporation portion is formed with the V-shaped grooves on the surface. In general, the liquid-phase working fluid in the grooves has a thin liquid film zone in the vicinity of the meniscus. The V-shaped groove has a large thin liquid film zone in the vicinity of the meniscus, compared to a U-shaped groove or a concave groove. Heat from the evaporation portion is transferred with higher heat transfer coefficient in the thin liquid film zone than the heat transfer coefficient of the working fluid other than the thin liquid film zone. So, evaporation efficiency in the thin liquid film zone is higher than evaporation efficiency of the liquid-phase working fluid other than the thin liquid film zone. Accordingly, the V-shaped groove having the large thin liquid film zone realizes higher heat transfer coefficient and evaporation efficiency than those of a U-shaped groove and a concave groove.

According to the embodiment of the present invention, the evaporation portion is made of nanomaterial such as carbon nanotube having higher thermal conductivity and is formed with the V-shaped grooves realizing higher evaporation efficiency. Accordingly, the heat transport device realizes extremely higher heat radiation efficiency without being made larger. In the heat transport device, each of the V-shaped grooves may have a bottom angle 2θ (10≦2θ≦130) and a width a, a relationship of the bottom angle 2θ (10≦2θ≦130) and the width a being a≦11*2θ+50 and a ≧0.3*2θ+1.

According to the embodiment of the present invention, in the V-shaped groove, in a case where a bottom angle 28 is larger, a groove width a or a working fluid width is smaller when a meniscus surface is in the highest position, and a contact angle of the working fluid with respect to a groove wall surface is smaller, higher evaporation efficiency is realized. The V-shaped groove having the width a and the bottom angle 2θ (10≦2θ≦130), the relationship thereof being a ≦11*2θ+50 and a≧0.3*2θ+1, has higher evaporation efficiency (* denotes multiplication).

In the heat transport device, the V-shaped grooves may be provided on the surface of the evaporation portion in a concentric manner and in a radial manner. In the heat transport device, the V-shaped grooves may be provided on the surface of the evaporation portion in a spiral manner and in a radial manner.

According to the embodiment of the present invention, the grooves of the above arrangement help the liquid-phase working fluid to flow in the circular direction and diametrical direction of the surface of the evaporation portion. That is, the working fluid can flow in the entire grooves. Thus, the liquid-phase working fluid can efficiently flow with a capillary force.

In the heat transport device, a distance between a back surface of the evaporation portion and a bottom portion of each of the V-shaped grooves may be 1 μm or more.

According to the embodiment of the present invention, the evaporation portion has a solid portion having a thickness of 1 μm or more between the back surface of the evaporation portion and the bottom portion of the grooves. Because heat from a heat source is transmitted to this portion, thermal conductivity of the entire evaporation portion improves. Further, when forming the grooves, a substrate or the like may not be damaged. So, the working fluid may not enter between the bottom portion of the grooves and the back surface of the evaporation portion through the damaged portion to peel off the evaporation portion.

In the heat transport device, the surface of the evaporation portion may have hydrophilicity.

According to the embodiment of the present invention, in a case of using pure water as the working fluid, the evaporation surface made of carbon nanotube having hydrophobicity is subjected to a hydrophilic processing. The contact angle of the working fluid is thus decreased. By decreasing the contact angle, the thin liquid film zone of the working fluid can be made larger. As the thin liquid film zone is larger, the more working fluid evaporates, with the result that evaporation efficiency increases.

According to another embodiment of the present invention, there is provided an electronic apparatus including a heat source and a heat transport device. The heat transport device includes an evaporation portion made of nanomaterial, a flow path, a condenser portion, and a working fluid. The heat transport device is thermally connected to the heat source. The evaporation portion has V-shaped grooves formed on a surface. The flow path communicates with the evaporation portion. The condenser portion communicates with the evaporation portion through the flow path. The working fluid evaporates from a liquid phase to a vapor phase in the evaporation portion and condenses from the vapor phase to the liquid phase in the condenser portion.

According to the embodiment of the present invention, in the heat transport device thermally connected to the heat source of the electronic apparatus, the liquid-phase working fluid evaporates to be a vapor phase in the evaporation portion. The vapor-phase working fluid condenses to be the liquid phase in the condenser portion. The phase transition is repeatedly performed in the heat transport device. Because the evaporation portion has the grooves on the surface, the area of the surface that contacts the working fluid is increased compared to an evaporation portion which is subjected to no surface processing. The liquid-phase working fluid flows in the grooves with a capillary force, with the result that the working fluid is spread over the entire grooves.

The evaporation portion of the heat transport device is made of nanomaterial, for example, carbon nanotube. The carbon nanotube has approximately 10 times higher thermal conductivity than copper, a typical metal material of a metal heat spreader, for example. Accordingly, by providing the evaporation portion made of carbon nanotube, extremely improved heat transmission efficiency is obtained compared to a heat transport device mainly made of a metal material.

The evaporation portion of the heat transport device is formed with the V-shaped grooves on the surface. In general, the liquid-phase working fluid in the grooves has a thin liquid film zone in the vicinity of the meniscus. The V-shaped groove has a large thin liquid film zone in the vicinity of the meniscus, compared to a U-shaped groove or a concave groove. Heat from the evaporation portion is transmitted with higher heat transfer coefficient in the thin liquid film zone than the heat transfer coefficient of the working fluid other than the thin liquid film zone. So, evaporation efficiency in the thin liquid film zone is higher than evaporation efficiency of the liquid-phase working fluid other than the thin liquid film zone. Accordingly, the V-shaped groove having the large thin liquid film zone realizes higher heat transfer efficiency and evaporation efficiency than those of a U-shaped groove and a concave groove.

According to the embodiment of the present invention, the evaporation portion of the heat transport device is made of nanomaterial such as carbon nanotube having higher thermal conductivity and is formed with the V-shaped grooves realizing higher evaporation efficiency. Accordingly, a heat transport device realizing extremely higher heat radiation efficiency without being made larger is realized.

According to the embodiment of the present invention, because the heat source is thermally connected to the evaporation portion of the heat transport device, the heat transport device efficiently diffuses the heat from the heat source.

According to another embodiment of the present invention, there is provided a heat transport device manufacturing method. A catalyst layer is formed on a substrate constituting an evaporation portion. A nanomaterial layer is formed on the catalyst layer. V-shaped grooves are formed on the nanomaterial layer by one of turning tool processing and press molding.

According to the embodiment of the present invention, the nanomaterial layer is formed. For example, carbon nanotube is densely produced to form a carbon nanotube layer. The carbon nanotube layer is treated as a single material and processed with a turning tool. Specifically, by minutely bending the densely-produced carbon nanotube with a turning tool, a micrometer-order structure can be formed. This processing method is easier than cutting a substrate made of, for example, a metal material, the cost thereof is lower than the cost of etching, and an excellent minute processability is realized. In the case of performing the turning tool processing, the turning tool may be lower in hardness than the catalyst layer as a base layer. In this case, the catalyst layer, the substrate, and the turning tool itself are not scratched when processing. The evaporation portion is thus free from scratch or separation. Also in the case of forming the grooves by press molding using a die, the die may be made of a material lower in hardness than the metal material of the catalyst layer. Also in this case, the catalyst layer, the substrate, and the turning tool itself are not scratched when processing. The evaporation portion is thus free from scratch or separation.

In the heat transport device manufacturing method, the-V-shaped grooves may be formed on the nanomaterial layer such that a distance between the catalyst layer and a bottom portion of each of the V-shaped grooves is 1 μm or more.

According to the embodiment of the present invention, the evaporation portion has a solid portion having a thickness of 1 μm or more between the bottom portion of the grooves and the catalyst layer. Because heat from the heat source is transmitted to this portion, thermal conductivity of the entire evaporation portion improves. Further, when forming the grooves, the catalyst layer or the like may not be damaged. So, the working fluid may not enter between the bottom portion of the grooves and the catalyst layer through the damaged portion to peel off the catalyst layer.

In the heat transport device manufacturing method, a surface of the nanomaterial layer may be subjected to a hydrophilic processing.

According to the embodiment of the present invention, the nanomaterial is, for example, carbon nanotube having hydrophobicity. In a case of using pure water as the working fluid, for example, the evaporation surface made of carbon nanotube is subjected to a hydrophilic processing. The contact angle of the working fluid is thus decreased. By decreasing the contact angle, the thin liquid film zone of the working fluid can be made larger. As the thin liquid film zone is larger, the more working fluid evaporates, with the result that evaporation efficiency increases.

According to another embodiment of the present invention, there is provided a heat transport device manufacturing method. A catalyst layer is formed on a substrate constituting an evaporation portion. A reactive gas is caused to flow between the substrate provided with the catalyst layer and a die to form a nanomaterial layer having V-shaped grooves on a surface.

According to the embodiment of the present invention, it is not necessary to perform cutting, so the fear of scratching the catalyst layer as the base layer and the substrate is further decreased.

In the heat transport device manufacturing method, a surface of the nanomaterial layer may be subjected to a hydrophilic processing.

According to the embodiment of the present invention, the nanomaterial is, for example, carbon nanotube having hydrophobicity. In a case of using pure water as the working fluid, for example, the evaporation surface made of carbon nanotube is subjected to a hydrophilic processing. The contact angle of the working fluid is thus decreased. By decreasing the contact angle, the thin liquid film zone of the working fluid can be made larger. As the thin liquid film zone is larger, the more working fluid evaporates, with the result that evaporation efficiency increases.

According to another embodiment of the present invention, there is provided a heat transport device manufacturing method. V-shaped grooves are formed on a substrate constituting an evaporation portion. A catalyst layer is formed on the substrate. A nanomaterial layer is formed on the catalyst layer.

According to the embodiment of the present invention, the fear of scratching the substrate and the like is further decreased.

In the heat transport device manufacturing method, a surface of the nanomaterial layer may be subjected to a hydrophilic processing.

According to the embodiment of the present invention, the nanomaterial is, for example, carbon nanotube having hydrophobicity. In a case of using pure water as the working fluid, for example, the evaporation surface made of carbon nanotube is subjected to a hydrophilic processing. The contact angle of the working fluid is thus decreased. By decreasing the contact angle, the thin liquid film zone of the working fluid can be made larger. As the thin liquid film zone is larger, the more working fluid evaporates, with the result that evaporation efficiency increases.

According to the heat transport device of the embodiments of the present invention, higher heat radiation efficiency is realized without being made larger.

According to the heat transport device manufacturing method of the embodiments of the present invention, easier manufacture, lower cost, and higher reliability are realized.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is a side view showing a heat spreader of a first embodiment of the present invention, the heat spreader being thermally connected to a heat source;

FIG. 2 is a plan view showing the heat spreader of FIG. 1;

FIG. 3 is a sectional view showing the heat spreader taken along the line A-A of FIG. 2;

FIG. 4 is a sectional view showing the heat spreader taken along the line B-B of FIG. 3;

FIG. 5 is a schematic plan view showing an evaporation portion of FIG. 3 seen from an evaporation surface side;

FIG. 6 is a perspective view showing the evaporation portion of FIG. 3;

FIG. 7 is a sectional view showing the evaporation portion taken along the line C-C of FIG. 5;

FIG. 8 is an enlarged sectional perspective view showing part of the evaporation portion taken along the line D-D of FIG. 6;

FIG. 9 is a partial sectional view of a groove of the evaporation portion provided to a heat reception plate via a base layer, the section being orthogonal to the longitudinal direction of the groove;

FIG. 10 is a schematic diagram showing the groove of FIG. 9 that contains a liquid refrigerant;

FIG. 11 is a schematic diagram showing the groove;

FIG. 12 is a graph showing dependency of a pressure loss difference ΔP with respect to a groove width a in a case where a bottom angle 2θ is varied;

FIG. 13 is a graph showing dependency of the groove width a with respect to the bottom angle 2θ in a case of the pressure loss difference ΔP=0;

FIG. 14 is a schematic diagram for explaining an operation of the heat spreader;

FIG. 15 is a flowchart showing a manufacturing method of the heat spreader according to an embodiment of the present invention;

FIG. 16 is a perspective view showing part of a turning tool;

FIGS. 17 are schematic diagrams showing in sequence an injection method of the refrigerant into the container and a method of sealing the container;

FIG. 18 is a side view showing a heat spreader of a second embodiment of the present invention, the heat spreader being thermally connected to a heat source;

FIG. 19 is an exploded perspective view of the heat spreader of FIG. 18;

FIG. 20 is a sectional view showing part of the heat spreader of FIG. 18;

FIG. 21 is a perspective view showing an inner portion of a heat reception plate;

FIG. 22 is a perspective view showing part of two laminated capillary plate members;

FIG. 23 is a plan view showing part of a capillary plate member group;

FIG. 24 is a sectional view showing the capillary plate member group taken along the line F-F of FIG. 23;

FIG. 25 is a plan view showing the entire capillary plate member;

FIG. 26 is a perspective view showing part of two laminated vapor-phase plate members;

FIG. 27 is a plan view showing the entire vapor-phase plate member;

FIG. 28 is a plan view showing an entire vapor-phase plate member, the vapor-phase plate member forming a pair with the vapor-phase plate member of FIG. 27;

FIG. 29 is a schematic sectional view showing a heat spreader according to a third embodiment of the present invention;

FIG. 30 is a plan view showing the heat spreader of FIG. 29;

FIG. 31 is a flowchart showing a manufacturing method of the heat spreader according to another embodiment of the present invention;

FIG. 32 is a schematic view showing ribs of the heat spreader according to another embodiment of the present invention;

FIG. 33 is a perspective view showing a desktop PC as an electronic apparatus including the heat spreader;

FIG. 34 is a graph showing a range where a meniscus radius is 2 mm or less;

FIG. 35 is a graph showing dependency of a degree of superheat T with respect to the groove width a in a case where the bottom angle 2θ is varied;

FIG. 36 is a graph showing dependency of the groove width a with respect to the bottom angle 2θ where T=100;

FIG. 37 is a graph showing the V shape of the groove obtained by the conditions of the pressure loss difference ΔP of the capillary force and the liquid refrigerant, the capillary length κ⁻¹, and the degree of superheat T;

FIG. 38 is a sectional view showing a heat pipe as a modified example of the heat transport device;

FIG. 39 is a perspective view showing a nanomaterial layer provided in the heat pipe of FIG. 38;

FIG. 40 is a schematic diagram for explaining an operation of the heat pipe of FIG. 38;

FIG. 41 is a sectional view showing a CPL as another modified example of the heat transport device; and

FIG. 42 is a schematic view for explaining an operation of the CPL of FIG. 41.

### DESCRIPTION OF PREFERRED EMBODIMENTS

Hereinafter, embodiments of the present invention will be described with reference to the drawings. In the following embodiments, description will be made while employing a heat spreader as a heat transport device.

### First Embodiment

(Structure of Heat Spreader)

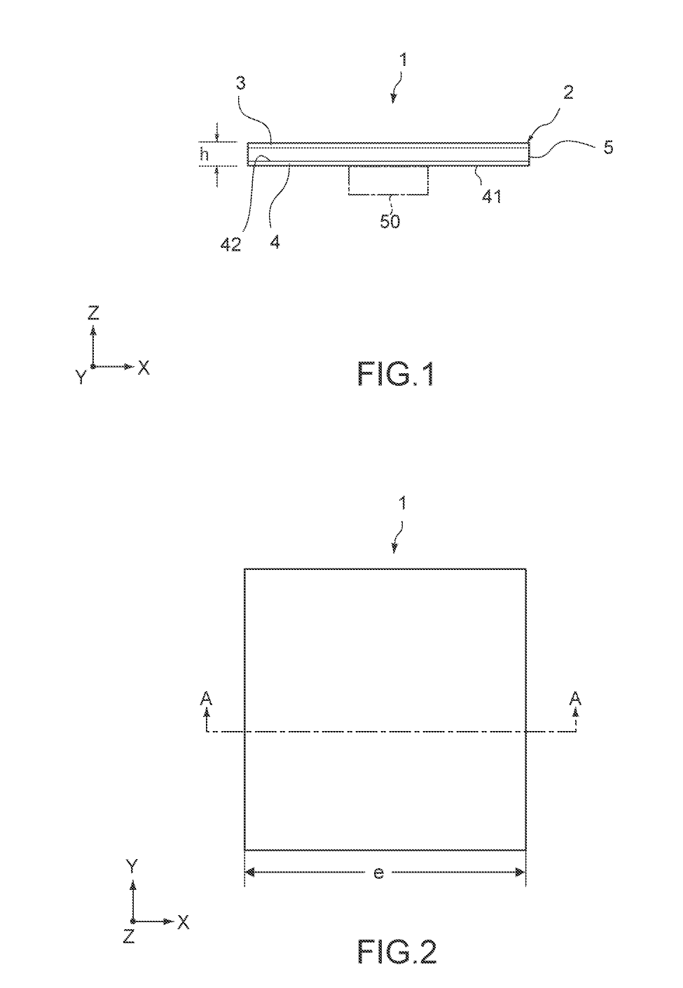

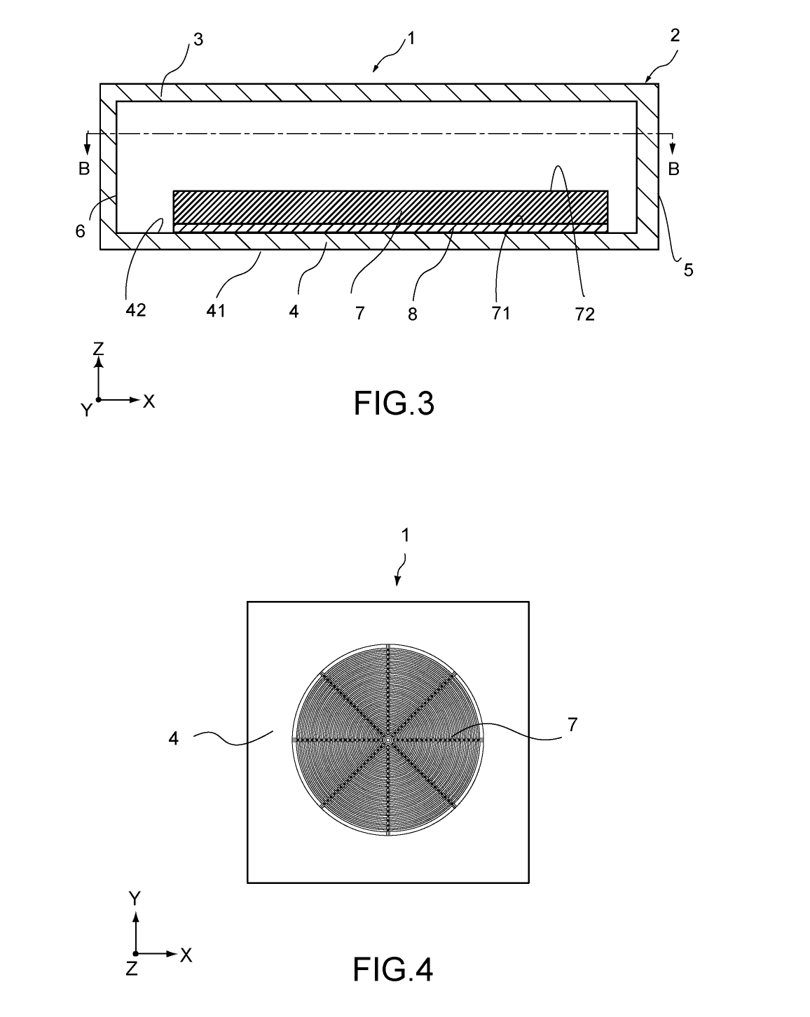

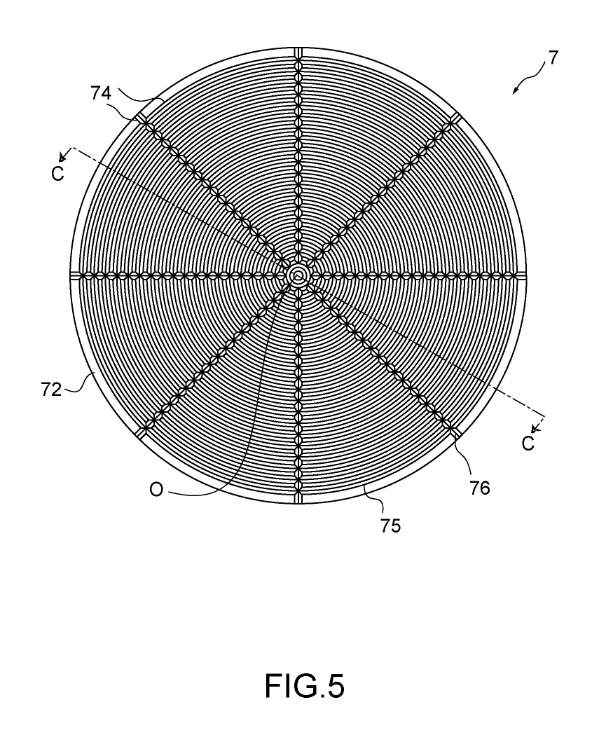

FIG. 1 is a side view showing a heat spreader of a first embodiment of the present invention, the heat spreader being thermally connected to a heat source. FIG. 2 is a plan view showing the heat spreader of FIG. 1. FIG. 3 is a sectional view showing the heat spreader taken along the line A-A of FIG. 2. FIG. 4 is a sectional view showing the heat spreader taken along the line B-B of FIG. 3.

As shown in FIGS. 1-4, a heat spreader 1 includes a container 2, a refrigerant (working fluid, not shown), a flow path 6 for the refrigerant, and an evaporation portion 7.

As shown in FIG. 1, the container 2 includes a heat reception plate 4, a heat radiation plate 3, and sidewalls 5. The heat reception plate 4 serves as a heat reception side. The heat radiation plate 3 is provided so as to face the heat reception plate 4 and serves as a heat radiation side. The sidewalls 5 tightly bond the heat reception plate 4 and the heat radiation plate 3. The heat reception plate 4 includes a heat reception surface 41 and an evaporation surface 42. The heat reception surface 41 corresponds to an outer surface of the container 2. The evaporation surface 42 faces the heat radiation plate 3. A heat source 50 is thermally connected to the heat reception surface 41. The phrase thermally connected means, in addition to direct connection, connection via a thermal conductor, for example. The heat source 50 is, for example, an electronic component such as a CPU and a resistor, or another device that generates heat.

As shown in FIG. 3, an inner space of the container 2 mainly serves as the flow path 6 for the refrigerant (not shown).

A base layer 8 is provided on the heat reception plate 4. The evaporation portion 7 is provided on the base layer 8.

As shown in FIG. 4, the evaporation portion 7 is substantially circular in the plan view. The evaporation portion 7 is provided on a substantially center portion of the evaporation surface 42 of the heat reception plate 4.

Note that in the specification, the “heat reception side” may include not only the heat reception plate 4 but also a zone of the inner space of the container 2 in the vicinity of the heat reception plate 4. The zone of the “heat reception side” may be shifted according to the amount of heat generated by the heat source 50 or the like. Similarly, the “heat radiation side” may include not only the heat radiation plate 3 but also a zone of the inner space of the container 2 in the vicinity of the heat radiation plate 3. The zone of the inner space of the container 2 in the vicinity of the heat radiation plate 3 may be referred to as “condenser portion”.

As shown in FIG. 2, the heat spreader 1 is substantially square in the plan view. However, the shape of the heat spreader 1 is not limited to the above and may be an arbitrary shape. The heat spreader 1 is 30-50 mm length (e) on each side, for example. As shown in FIG. 1, the heat spreader 1 is substantially rectangular in the side view. The heat spreader 1 is 2-5 mm height (h), for example. The heat spreader 1 having such a size is for a CPU of a PC as the heat source 50 thermally connected to the heat spreader 1. The size of the heat spreader 1 may be defined in accordance with the size of the heat source 50. For example, in a case where the heat source 50 thermally connected to the heat spreader 1 is a heat source of a large-sized display or the like, the length e may be set to about 2600 mm.

The size of the heat spreader 1 is defined such that the refrigerant can flow and condense appropriately. The operating temperature range of the heat spreader 1 is for example −40° C. to +200° C., approximately. The endothermic density of the heat spreader 1 is for example 8 W/mm² or lower.

The heat radiation plate 3, the heat reception plate 4, and the sidewalls 5 are made of a metal material, for example. The metal material is for example, copper, stainless steel, or aluminum, but not limited to the above. Other than the metal, a material having a high thermal conductivity such as carbon may be employed. All of the heat radiation plate 3, the heat reception plate 4, and the sidewalls 5 may be formed of different materials respectively, two of them may be formed of the same material, or all of them may be made of the same material. The heat radiation plate 3, the heat reception plate 4, and the sidewalls 5 may be bonded by brazing, that is, welded, or may be bonded with an adhesive material depending on the materials.

The base layer 8 is a catalyst layer of metal, for example, for forming the evaporation portion 7. The metal material is, for example, aluminum or titanium, but not limited to the above. In a case where the material of the heat radiation plate 3 may be a catalyst for the evaporation portion 7, the base layer 8 may not be prepared.

As the refrigerant, pure water, alcohol such as ethanol, methanol, or isopropyl alcohol, chlorofluorocarbon, hydrochlorofluorocarbon, fluorine, ammonia, acetone, or the like may be used, but not limited to the above. Meanwhile, in view of latent heat or preserve of the global environment, pure water is preferable.

The evaporation portion 7 is made of carbon nanotube. The carbon nanotube has approximately 10 times higher thermal conductivity than copper, a typical metal material of a metal heat spreader, for example. Accordingly, in a case where the evaporation portion 7 is made of carbon nanotube, extremely improved heat transfer efficiency is obtained compared to a heat spreader mainly made of a metal material. The carbon nanotube has hydrophobicity. At least an evaporation surface 72 of the evaporation portion 7 made of carbon nanotube may be subjected to a hydrophilic processing, in a case where pure water is used as the refrigerant.

Note that in FIG. 3, for easier understanding, the shape of the members is changed from the actual configuration. For example, the scale ratio of the evaporation portion 7 with respect to the container 2 is made larger than the actual configuration.

In FIG. 4, the evaporation portion 7 is substantially circular in a plan view and is provided on a substantially center portion of the evaporation surface 42 of the heat reception plate 4, but not limited to the above. The shape of the evaporation portion 7 in a plan view may be substantially ellipsoidal or polygonal, or another arbitrary shape. The diameter of the evaporation portion 7 is about 30 mm, for example, but not limited to the above. The thickness of the evaporation portion 7 is, for example, 10-50 μm, typically about 20 μm. The size of the evaporation portion 7 is arbitrarily changed according to the amount of heat generated by the heat source 50. The mount area of the evaporation portion 7 on the evaporation surface 42 of the heat reception plate 4 is not limited to the substantially center portion of the evaporation surface 42. The evaporation portion 7 may be provided on another arbitrary area. The scale ratio of the evaporation portion 7 with respect to the evaporation surface 42 of the heat reception plate 4 is not limited to that shown in the drawings, and is arbitrarily changed.

(Structure of Evaporation Portion)

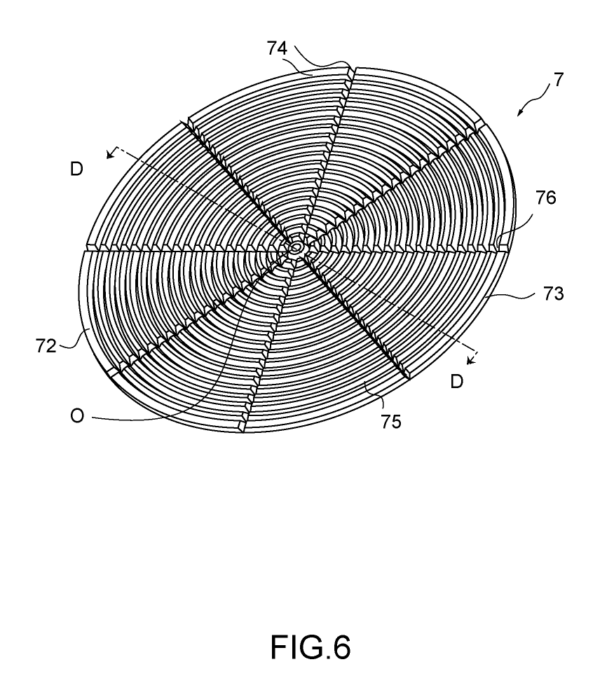

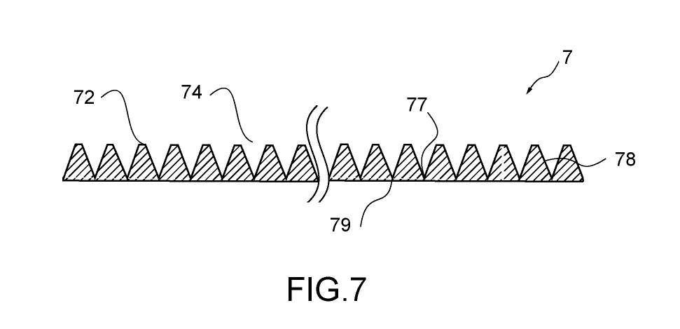

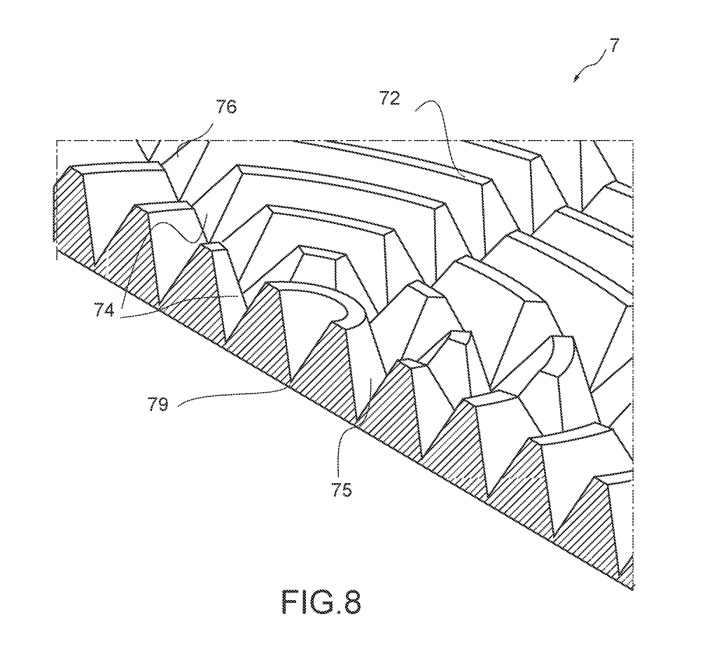

FIG. 5 is a schematic plan view showing the evaporation portion 7 of FIG. 3 seen from the evaporation surface 72 side. FIG. 6 is a perspective view showing the evaporation portion 7. FIG. 7 is a sectional view showing the evaporation portion 7 taken along the line C-C of FIG. 5. FIG. 8 is an enlarged sectional perspective view showing part of the evaporation portion 7 taken along the line D-D of FIG. 6.

As shown in FIGS. 5-8, the evaporation portion 7 includes the evaporation surface 72, a heat reception surface 71, and a side surface 73. The evaporation surface 72 is a front surface of the evaporation portion 7. The heat reception surface 71 is a back surface of the evaporation portion 7. The side surface 73 is, for example, orthogonal to the evaporation surface 72 and the heat reception surface 71, but not limited to the above. Grooves 74 are provided on the evaporation surface 72. The grooves 74 include circumferential grooves 75 and diametrical grooves 76. The circumferential grooves 75 are numerous concentric circles with a center point O of the evaporation surface 72 being a center. The diametrical grooves 76 are in a radial pattern to pass through the center point O. Note that the number of the circles and the number of the radial grooves are not limited to those shown in the drawings.

The arrangement of the grooves 74 is not limited to the above. The grooves 74 may be arbitrarily arranged as long as the refrigerant can flow in the entire grooves 74. For example, the circumferential grooves 75 may be concentric polygons, concentric ellipsoids, or a spiral with the center point O being a center. Alternatively, the grooves 74 may not be circular and diametrical, but may be substantially grid-like. Also in those cases, the number of the concentric polygons, concentric ellipsoids, spiral, or grid is not limited.

The grooves 74 of the above arrangement help the liquid-phase refrigerant (liquid refrigerant) to flow in the circular direction and diametrical direction of the evaporation surface 72 of the evaporation portion 7. Thus, the liquid refrigerant can flow in the entire grooves 74. Accordingly, the liquid refrigerant can efficiently flow with a capillary force.

Note that in FIGS. 5-8, for easier understanding, the scale ratio of the grooves 74 with respect to the evaporation portion 7 is different from the actual configuration.

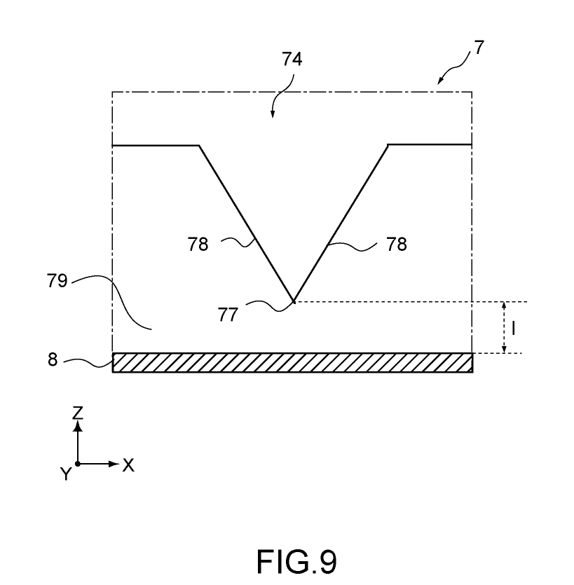

FIG. 9 is a partial sectional view of the groove 74 of the evaporation portion 7 provided on the base layer 8 on the heat reception plate 4, the section being orthogonal to the longitudinal direction of the groove 74. The groove 74 has a V-shaped section. The groove 74 has a bottom portion 77 and wall surfaces 78. The bottom portion 77 is a tip portion of the V shape.

The length 1 from the bottom portion 77 to the base layer 8 (distance between the back surface of the evaporation portion 7 and the bottom portion 77) is 1 μm or more, for example. In a case where the base layer 8 is not provided (not shown), the distance from the bottom portion 77 to the evaporation surface 42 is 1 μm or more, for example.

The evaporation portion 7 has a solid portion (lower portion 79) having a thickness of 1 μm or more between the bottom portion 77 of the grooves 74 and the heat reception surface 71. Because heat is transmitted to the lower portion 79, thermal conductivity of the entire evaporation portion 7 improves. Further, when the grooves 74 are formed on the evaporation surface 72 (described later), the base layer 8, the heat reception plate 4, and a processing tool may not be damaged. So, the refrigerant may not enter between the heat reception plate 4 and the base layer 8 through a damaged portion of the base layer 8 to peel off the entire base layer 8.

The depth of the groove 74 is, for example, 2-800 μm, specifically 30 μm. The depth of the groove 74 is defined such that the liquid refrigerant can flow in the grooves 74 with an appropriately capillary force. The width of the V shape of the groove 74 is, for example, about 10-100 μm. The V shape is symmetric with respect to the normal line crossing the tip portion corresponding to the bottom portion 77, but may not be symmetric.

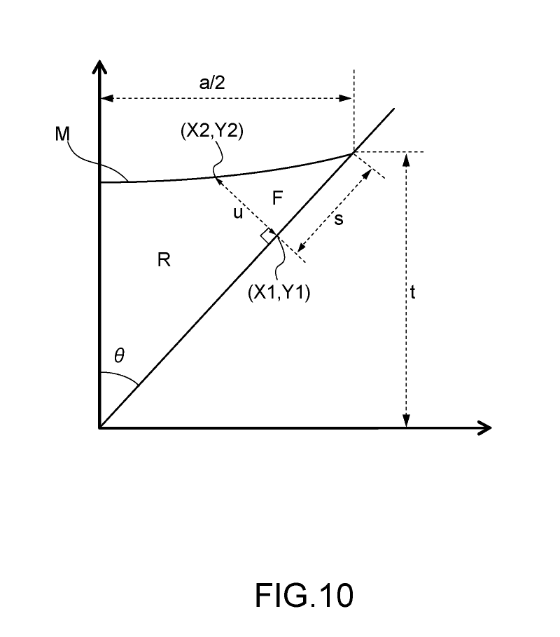

The liquid refrigerant in the groove 74 has a zone of a thin liquid film in the vicinity of the meniscus (hereinafter referred to as “thin liquid film zone F” to be described later. See FIG. 10). The groove 74 having the V shape has a large thin liquid film zone F in the vicinity of the meniscus, compared to a U-shaped groove or a concave groove, for example. Heat from the evaporation portion 7 is transferred with higher thermal conductivity in the thin liquid film zone F than thermal conductivity of the working fluid other than the thin liquid film zone F. So, evaporation efficiency in the thin liquid film zone F is higher than evaporation efficiency of the liquid refrigerant other than the thin liquid film zone F. Accordingly, the V-shaped groove 74 having the large thin liquid film zone F realizes higher thermal conductivity and evaporation efficiency than those of a U-shaped groove and a concave groove.

(Detailed Structure of V-Shaped Groove)

Next, the V shape of the groove 74 will be described. The V shape of the groove 74 is defined based on a pressure loss difference ΔP between the capillary force and the refrigerant, a capillary length κ⁻¹, and a degree of superheat T.

Note that a bottom angle 2θ, of the V-shaped groove 74 is 10°≦2θ≦130°. In a case of 2θ<10°, it is difficult to machine-form the V-shaped groove 74. Even though the V-shaped groove 74 having the bottom angle 2θ(2θ<10°) is formed, the amount of the vapor-phase refrigerant (vapor refrigerant) evaporating from the surface of the liquid refrigerant in the V-shaped groove 74 is small. In a case of 2θ>130°, the heat is spread in the refrigerant in the groove 74 and the thus-caused resistance becomes large.

Here, the pressure loss difference ΔP will be described. In a case of the pressure loss difference ΔP>0, the liquid refrigerant can flow with a capillary force.

The refrigerant can circulate in the heat spreader 1 if the capillary force is larger than the total pressure loss such as a flow path resistance. The following expression (1) shows the pressure relationship.

ΔP_{cap}≧ΔP_{w}+ΔP₁+ΔPᵥ (1)

in which ΔP_{cap} is a capillary force, ΔP_{w} is a pressure loss of the wick, ΔP₁ is a pressure loss of the liquid refrigerant, and ΔPᵥ is a pressure loss of the vapor refrigerant.

Assuming a case where the pressure loss of the vapor refrigerant can be neglected in the vapor phase flow path, the following expression (2) is established.

ΔP_{cap}≧ΔP_{w}+ΔP₁ (2)

Then the pressure loss difference ΔP is obtained as shown in the following expression (3).

ΔP=ΔP_{cap}−(ΔP_{w}+ΔP₁) (3)

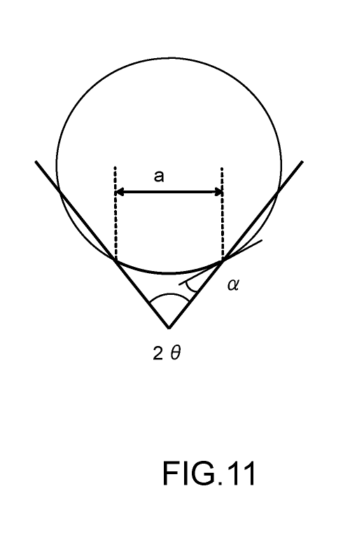

FIG. 11 is a schematic diagram showing the groove 74.

In FIG. 11, M is the meniscus surface, which is a surface of the liquid refrigerant in the groove 74. a is the opening width of the groove 74, which is substantially same as the width of the liquid refrigerant in the groove 74. a is a contact angle of the liquid refrigerant in the groove 74 to the wall surfaces 78. 20 is the bottom angle of the V shape as described above. The capillary force ΔP_{cap} is represented by the following expression (4).

ΔP_{cap}=2δ cos(θ+α)/a (4)

As the contact angle a becomes smaller, the capillary force ΔP_{cap} becomes larger. At least the evaporation surface 72 of the evaporation portion 7 is subjected to a hydrophilic processing. The contact angle α is close to 0, and α=0 is thus assumed. A surface tension δ is calculated assuming that the surface tension δ of pure water at 100° C. is a constant value. The flow path resistance (pressure loss) is obtained by the following expressions.

$$\begin{matrix}Δ {P}_{w} + Δ {P}_{l} = \frac{{μ}_{l} {\dot{m}}_{l} L}{{A}_{w} {ρ}_{l} K} & ( 5 ) \\ K = \frac{{D}_{h}^{2} ϕ}{2 ( f {Re}_{l , h} )} & ( 6 ) \\ {D}_{h} = a cos θ & ( 7 ) \\ ϕ = \frac{a}{2 V} & ( 8 ) \\ f {Re}_{l , h} = \frac{12 ( B + 2 ) ( 1 - {tan}^{2} θ )}{( B - 2 ) {( tan θ + {( 1 + {tan}^{2} θ )}^{0.5} )}^{0.5}} & ( 9 ) \\ B = {( 4 + \frac{5}{2} ( {cot}^{2} θ - 1 ) )}^{0.5} & ( 10 )\end{matrix}$$

TABLE 1

| | |
|---|---|
| μₗ | coefficient of viscosity of liquid |
| | refrigerant |
| mₗ | volume flow rate |
| L | flow path length |
| A_{w} | flow path section area |
| ρₗ | density of liquid refrigerant |
| a | flow path width (groove width) |
| 2θ | bottom angle of V-shaped groove |
| V | pitch of V-shaped groove |

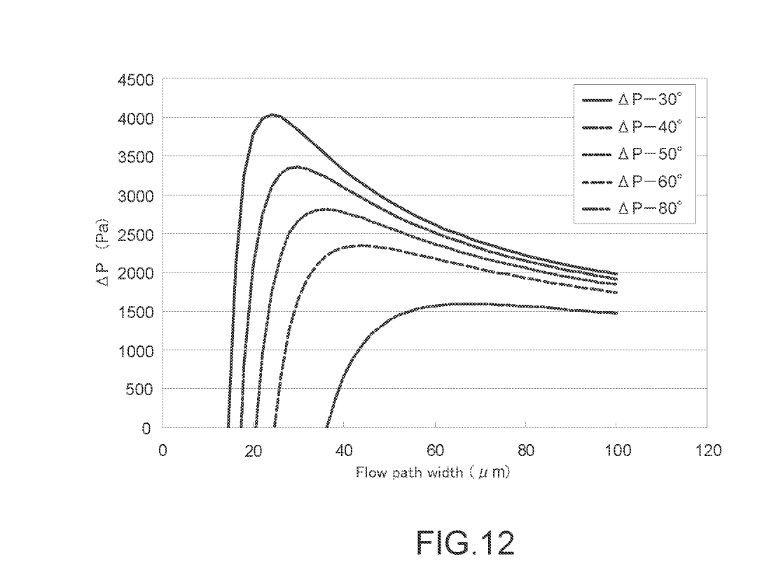

FIG. 12 is a graph showing dependency of the pressure loss difference ΔP with respect to the groove width a in a case where the bottom angle 2θ is varied. As the pressure loss difference ΔP is larger, the more liquid refrigerant flows. So, the groove width a may desirably be about 40 μm or less.

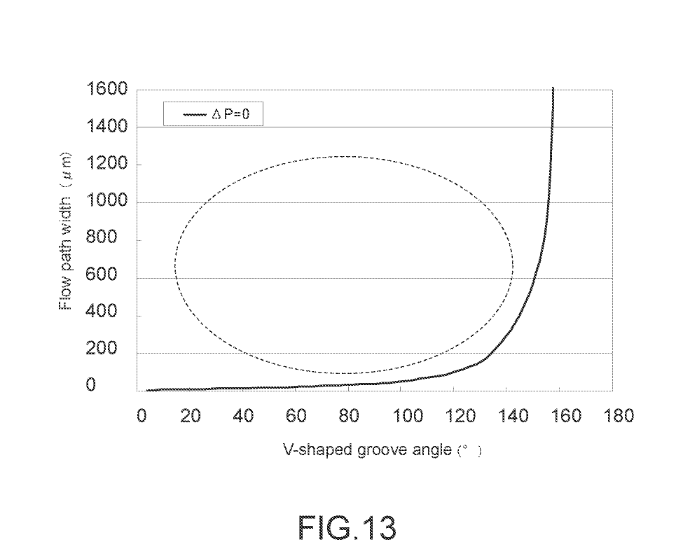

FIG. 13 is a graph showing dependency of the groove width a with respect to the bottom angle 2θ in a case of the pressure loss difference ΔP=0. As the pressure loss difference ΔP is larger, the more liquid refrigerant flows as described above. In FIG. 13, the left side of the graph (e.g., the area surrounded by the dashed oval) shows ΔP≧0.

Next, the capillary length κ⁻¹ will be described. The capillary length κ⁻¹ is generally about 2 mm. The capillary length κ⁻¹ is represented by the following expression (11).

$${κ}^{- 1} = \sqrt{\frac{γ}{ρ g}} \qquad ( 11 )$$

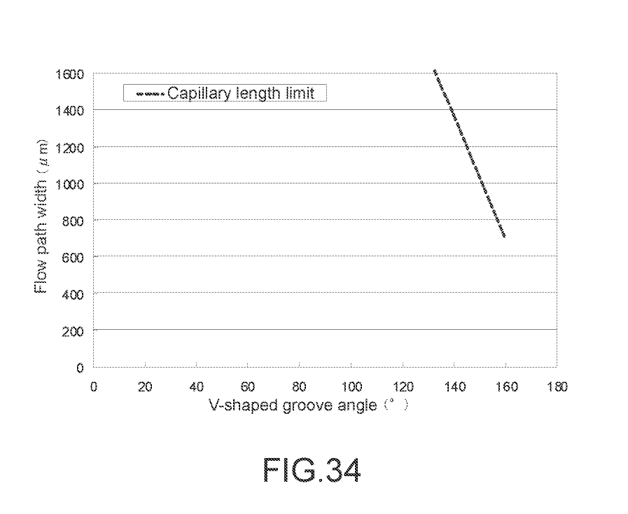

In a range where the meniscus radius is smaller than the capillary length κ⁻¹, the gravity can be neglected. In this range, a heat transport device in which the capillary length κ⁻¹ is dominant is obtained. In the case where the capillary length κ⁻¹ is about 2 mm, the meniscus radius may be about 2 mm or less. FIG. 34 shows the range where the meniscus radius is 2 mm or less.

With regard to the degree of superheat T, T≦100 is desirable.

FIG. 10 is a schematic diagram showing the groove 74 of FIG. 9 that contains the liquid refrigerant. Since in this embodiment, the V-shaped groove 74 is symmetric with respect to the normal line crossing the bottom portion 77, only the right half of the groove 74 from the normal line crossing the bottom portion 77 is shown.

The X axis is the horizontal direction, i.e., the width direction of the groove 74. The Y axis is the vertical direction, i.e., the depth direction of the groove 74. The origin point of the coordinates is the bottom portion 77. θ is the half of the bottom angle 2θ of the groove 74. The line crossing the origin point and extending with the angle θ is the wall surface 78 of the groove 74. The wall surface 78 is represented by the following expression (12).

Y1=(1/tan θ)X1 (12)

In FIG. 10, R is the liquid refrigerant in the groove 74. M is the surface of the liquid refrigerant R and is curved. The surface M of the liquid refrigerant R is a meniscus surface. a is the opening width of the groove 74. t is a depth of the liquid refrigerant in the groove 74, specifically, the depth from a point closest to the evaporation surface 72 to the bottom portion 77. t is substantially equal to the depth of the groove 74. s is a distance between an arbitrary point (X1, Y1) on the wall surface 78 represented by the expression (12) and a point (a/2, t). Here, 0<X1<a/2 and 0<Y1<t are established. A dashed line is a straight line orthogonal to the wall surface 78 represented by the expression (12), and is represented by the following expression (13).

Y2=(−tan θ)X2+(1/tan θ+tan θ)X1 (13)

A crossing point of the expression (13) and the curved line M is (X2, Y2). Here, 0<X2<a/2 and 0<Y2<t are established. u is a distance between (X1, Y1) and (X2, Y2). F is a substantially triangular zone formed by (X1, Y1), (X2, Y2), and a crossing point of the curved line M and the line represented by the expression (12), that is, F is the thin liquid film zone. Here, based on the one-dimensional model of FIG. 9, the V shape realizing the degree of superheat of 100° C. or less is estimated. To obtain the change of the temperature T of a bottom surface (substrate) of the V-shaped groove 74, it is assumed that the saturation temperature (temperature at which phase transition occurs) is 0° C. so as not to be affected by the saturation temperature.

It is assumed that thermal conductivity A and evaporation heat transfer coefficient h are as follows.

$$\begin{matrix}Q = h A ( {T}_{w} - {T}_{s} ) & ( 14 ) \\ Q = λ A \frac{T - {T}_{w}}{Y} & ( 15 )\end{matrix}$$

TABLE 2

| | |
|---|---|
| h | evaporation heat transfer coefficient (thin |
| | liquid film) 10⁷ W/m²K |
| A | area s * 3 mm (* denotes multiplication) |
| λ | thermal conductivity |
| Tₛ | saturation temperature (assumed to be 0° C. for |
| | considering superheat) |
| T_{w} | wall surface temperature |
| T | bottom surface (substrate) temperature |

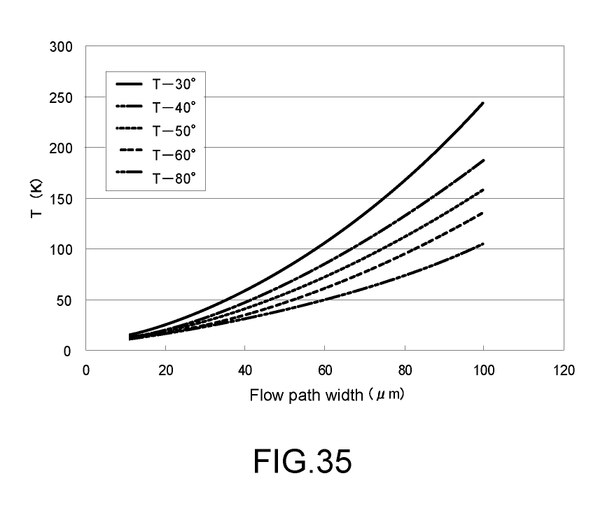

From the above expressions, the temperature T of the bottom surface (substrate) is obtained. FIG. 35 shows dependency of the degree of superheat T with respect to the groove width a in a case where the bottom angle 2θ is varied.

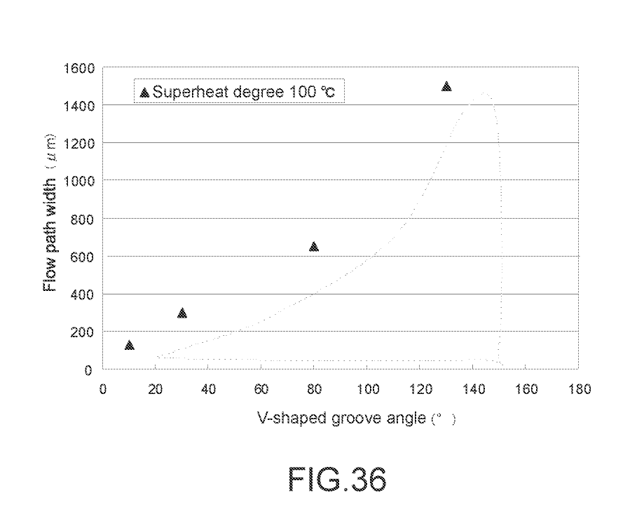

It is assumed that the superheat T≦100 is desirable. FIG. 36 shows dependency of the groove width a with respect to the bottom angle 2θ where T=100. As described above, in FIG. 36, the superheat T≦100, which is desirable, is shown in a right-side area of the graph, for example, the area surrounded by the dashed line.

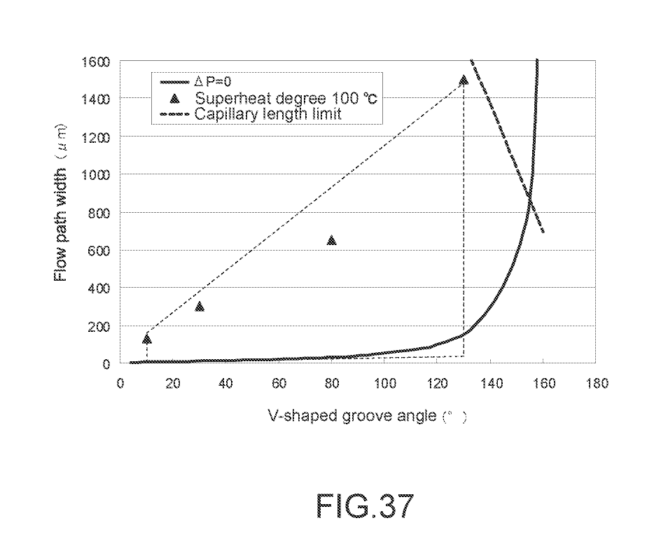

FIG. 37 is a graph showing the V shape of the groove 74 obtained by the above-mentioned conditions of the pressure loss difference ΔP of the capillary force and the liquid refrigerant, the capillary length κ⁻¹, and the degree of superheat T. Specifically, FIG. 37 includes the graphs of FIG. 13, FIG. 34, and FIG. 36. The V shape may have any shape corresponding to the area surrounded by the dashed line of FIG. 37. In the relationship of the bottom angle 2θ (10≦2θ≦130) and the width a of the V shape, the range of the V shape is a≦11*2θ+50 and a 0.3*2θ+1 (* denotes multiplication).

(Operation of Heat Spreader)

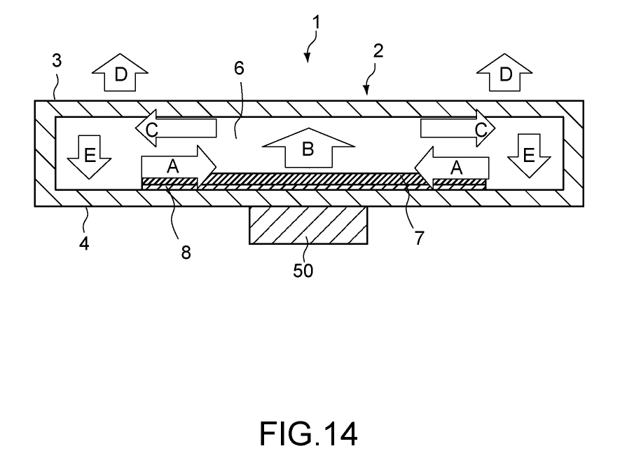

The operation of the heat spreader 1 as structured above will be described. FIG. 14 is a schematic diagram showing the operation.

When the heat source 50 generates heat, the heat reception plate 4 receives the heat. Then, the liquid refrigerant flows with a capillary force in the grooves 74 of the evaporation portion 7 on the heat reception side (arrow A). The liquid refrigerant evaporates from the heat reception plate 4 and specifically the evaporation portion 7 to be the vapor refrigerant. Some of the vapor refrigerant flows in the grooves 74, but most of the vapor refrigerant flows in the flow path 6 to the heat radiation side (arrow B). As the vapor refrigerant flows in the flow path 6, the heat diffuses, and the vapor refrigerant condenses in the condenser portion to be the liquid phase (arrow C). Thus the heat spreader 1 radiates the heat mainly from the heat radiation plate 3 (arrow D). The liquid refrigerant flows in the flow path 6 to return to the heat reception side (arrow E). By repeating the above operation, the heat spreader 1 transports the heat of the heat source 50.

The operational zones as shown by the arrows A to E in FIG. 14 are merely rough guide or rough standard and not clearly defined since respective operational zones may be shifted according to the amount of heat generated by the heat source 50 or the like.

Note that on the surface of the heat radiation plate 3 of the heat spreader 1, a heat radiation member (not shown) such as a heat sink may be thermally connected. In this case, the heat diffused by the heat spreader 1 is transferred to the heat sink and radiated from the heat sink.

As described above, in the heat spreader 1 of this embodiment, the liquid refrigerant in the grooves 74 of the evaporation portion 7 has the thin liquid film zone F in the vicinity of the meniscus. In this embodiment, the groove 74 having the V shape has a large thin liquid film zone F in the vicinity of the meniscus, compared to a U-shaped groove or a concave groove, for example. Heat from the evaporation portion 7 is transferred with higher heat transfer coefficient in the thin liquid film zone F than the heat transfer coefficient of the working fluid other than the thin liquid film zone F. So, evaporation efficiency in the thin liquid film zone F is higher than evaporation efficiency of the liquid refrigerant other than the thin liquid film zone F. Accordingly, the V-shaped groove 74 having the large thin liquid film zone F realizes larger heat transfer coefficient and evaporation efficiency than those of a U-shaped groove and a concave groove. In this embodiment, the evaporation portion 7 having the above structure realizes higher evaporation efficiency, so higher heat radiation efficiency is obtained without making the heat spreader 1 larger.

### Modified Example of Heat Transport Device

Next, modified examples of the heat transport device will be described. In the following, components, functions, and the like similar to those of the heat spreader 1 of the above embodiment will be attached with similar reference symbols, the description thereof will be simplified or omitted, and different part will mainly be described.

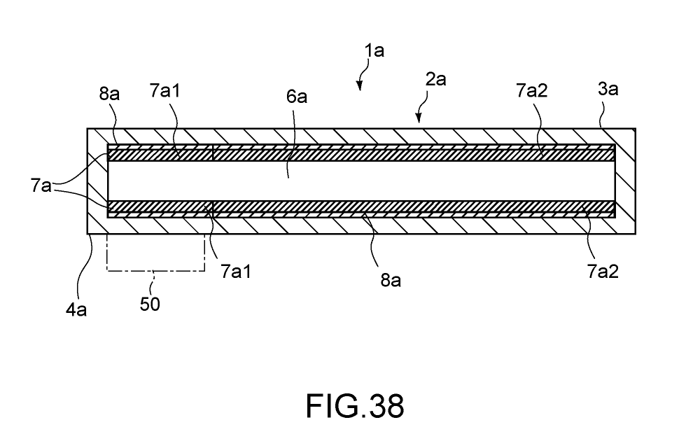

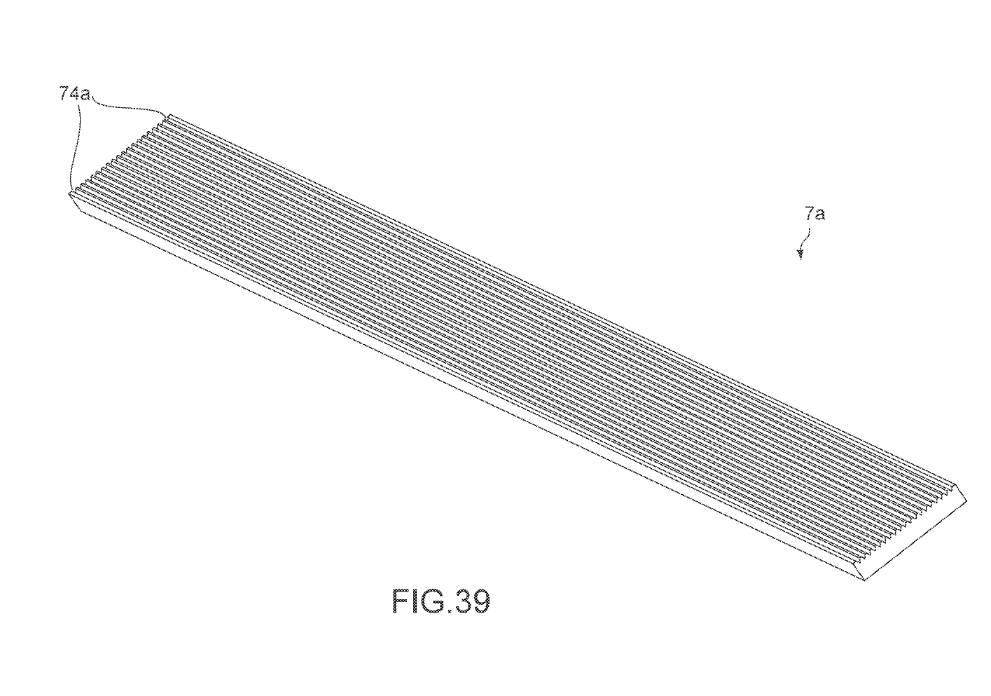

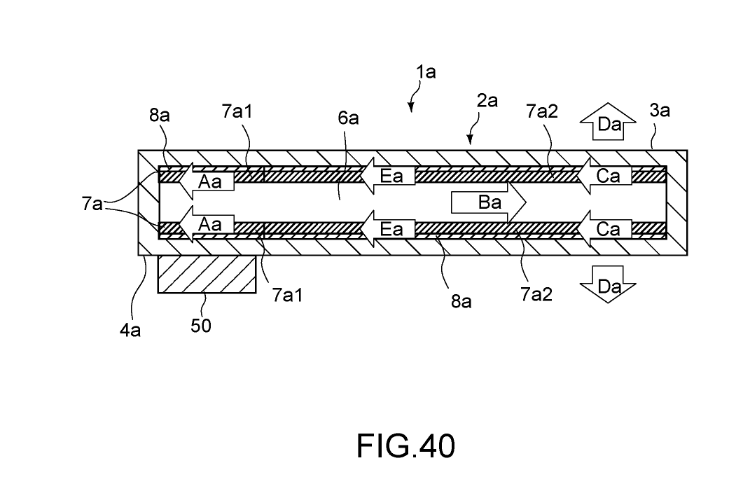

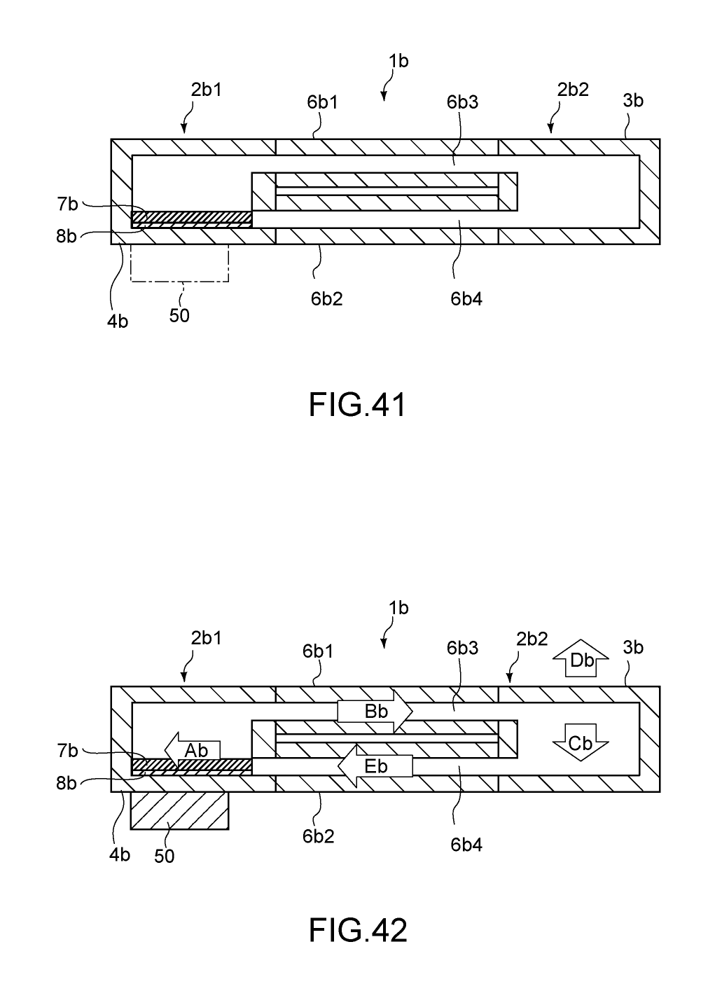

FIG. 38 is a sectional view showing a heat pipe as a modified example of the heat transport device. FIG. 39 is a perspective view showing a nanomaterial layer provided in the heat pipe of FIG. 38. FIG. 40 is a schematic diagram for explaining the operation of the heat pipe of FIG. 38. FIG. 41 is a sectional view showing a CPL as another modified example of the heat transport device. FIG. 42 is a schematic view for explaining the operation of the CPL of FIG. 41.

As shown in FIG. 38, a heat pipe 1a includes a container 2a and a refrigerant (working fluid, not shown). The heat source 50 is thermally connected to an area of an outer wall surface of the container 2a. This area functions as a heat reception portion 4a. An area of the container 2a facing the heat reception portion 4a functions as a heat radiation portion 3a. A base layer 8a is provided on an inner surface of the container 2a. A nanomaterial layer 7a is provided on the base layer 8a. On the surface of the nanomaterial layer 7a, elongated grooves 74a are formed as shown in FIG. 39. Specifically, the grooves 74a are provided on the nanomaterial layer 7a such that the heat reception portion 4a communicates with the heat radiation portion 3a via the grooves 74a. The area of the nanomaterial layer 7a corresponding to the heat reception portion 4a functions as an evaporation portion 7a1. The area of the nanomaterial layer 7a excluding the evaporation portion 7a1 functions as a liquid phase flow path 7a2 for the refrigerant. An inner space of the container 2a corresponding to the liquid phase flow path 7a2 functions as a vapor phase flow path 6a for the refrigerant.

As shown in FIG. 40, when the heat source 50 generates heat, the heat reception portion 4a receives the heat. Then, the liquid refrigerant flows with a capillary force in the grooves 74a of the evaporation portion 7a1 on the heat reception side (arrow Aa). The liquid refrigerant evaporates from the evaporation portion 7a1 to be the vapor refrigerant. Some of the vapor refrigerant flows in the grooves 74a, but most of the vapor refrigerant flows in the vapor phase flow path 6a to the heat radiation side (arrow Ba). As the vapor refrigerant flows in the vapor phase flow path 6a, the heat is transported, and the vapor refrigerant condenses to be the liquid phase (arrow Ca). Thus the heat pipe 1a radiates the heat mainly from the heat radiation portion 3a (arrow Da). The liquid refrigerant flows with a capillary force in the liquid phase flow path 7a2 to return to the heat reception side (arrow Ea). By repeating the above operation, similarly to the heat spreader 1, the heat pipe 1a transports the heat of the heat source 50.

As shown in FIG. 41, a CPL 1b includes a plurality of containers 2b1 and 2b2, a refrigerant (working fluid, not shown), a plurality of pipe portions 6b1 and 6b2, and an evaporation portion 7b. The container 2b1 constitutes a heat reception portion 4b. The container 2b2 constitutes a heat radiation portion 3b. The pipe portions 6b1 and 6b2 are connected to the containers 2b1 and 2b2, respectively, by welding, soldering, or the like. Accordingly, the pipe portions 6b1 and 6b2 are gas-tightly coupled to the containers 2b1 and 2b2, respectively, to constitute flow paths. The refrigerant thus flows between the heat reception portion 4b and the heat radiation portion 3b. Specifically, the pipe portion 6b1 constitutes a vapor phase flow path 6b3, and the pipe portion 6b2 constitutes a liquid phase flow path 6b4. Although not shown, for example, the nanomaterial layer 7a of FIG. 39 may be provided on an inner wall surface of the pipe portion 6b2 such that the grooves 74a communicate the heat reception portion 4b to the heat radiation portion 3b. A base layer 8b is provided on the container 2b1. The evaporation portion 7b having grooves on the surface, which is similar to the evaporation portion 7, is provided on the base layer 8b. The heat source 50 is thermally connected to the heat reception portion 4b.

As shown in FIG. 42, when the heat source 50 generates heat, the heat reception portion 4b receives the heat. Then, the liquid refrigerant flows with a capillary force in the grooves of the evaporation portion 7b on the heat reception side (arrow Ab). The liquid refrigerant evaporates from the evaporation portion 7b to be the vapor refrigerant. Some of the vapor refrigerant flows in the grooves, but most of the vapor refrigerant flows in the vapor phase flow path 6b3 to the heat radiation side (arrow Bb). As the vapor refrigerant flows in the vapor phase flow path 6b3, the heat is transported, and the vapor refrigerant condenses to be the liquid phase (arrow Cb). Thus the CPL 1b radiates the heat mainly from the heat radiation portion 3b (arrow Db). The liquid refrigerant flows in the liquid phase flow path 6b4 to return to the heat reception side (arrow Eb). By repeating the above operation, similarly to the heat spreader 1, the CPL 1b transports the heat of the heat source 50.

(Manufacturing Method of Heat Spreader)

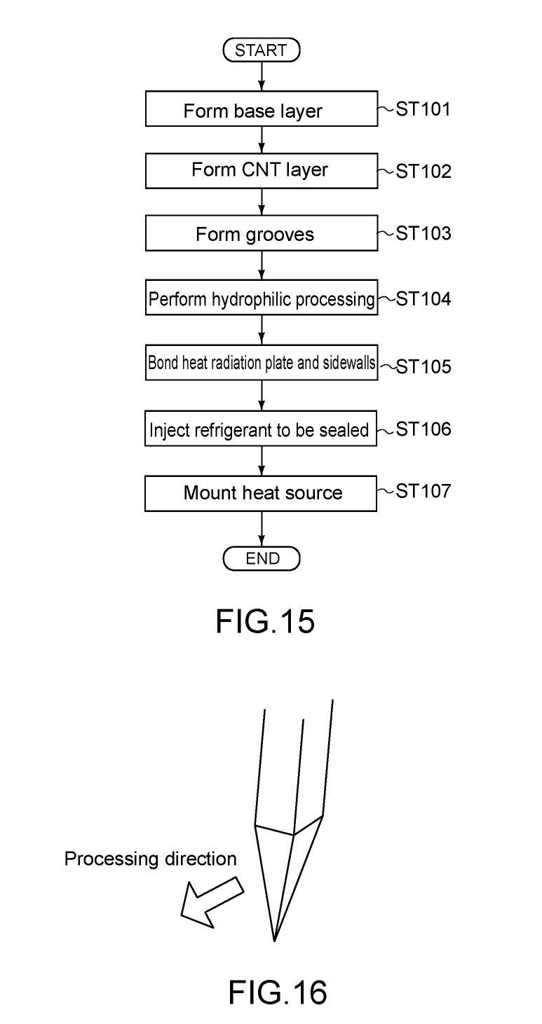

The heat spreader 1 of FIG. 1 and the like will be described again. A manufacturing method of the heat spreader 1 according to this embodiment will be described. FIG. 15 is a flowchart showing the manufacturing method of the heat spreader 1.

The base layer 8 is formed on the evaporation surface 42 of the heat reception plate 4 (Step 101). The base layer 8 is a catalyst layer on which carbon nanotube is produced.

Next, carbon nanotube is densely produced on the base layer 8 to form a carbon nanotube layer (Step 102). The carbon nanotube may be produced on the catalyst layer by plasma CVD (Chemical Vapor Deposition) or thermal CVD, but the production method of the carbon nanotube is not limited to the above. The evaporation surface 42 may be appropriately surface-processed as necessary. The surface of the heat radiation plate 3 that faces the heat reception plate 4 may also be appropriately surface-processed as necessary.

Next, the V-shaped grooves are formed on the surface of the carbon nanotube layer with a processing tool (turning tool) of FIG. 16 (Step 103). For example, in a case of forming the circumferential grooves 75, the turning tool may be moved circularly on the surface of the carbon nanotube layer. The evaporation portion 7 having the grooves 74 on the evaporation surface 72 is thus formed. In general, it is difficult to form a minute structure by machine-processing carbon nanotube having a micrometer-order structure, and such a minute structure is usually formed by etching. To the contrary, in this embodiment, the densely-grown carbon nanotube is treated as a single material (carbon nanotube layer). By minutely bending the carbon nanotube, a micrometer-order structure is formed. This processing method is easier than cutting a substrate made of, for example, a metal material, the cost thereof is lower than the cost of the etching, and an excellent minute processability is realized. The turning tool may be made of a material lower in hardness than the metal material constituting the base layer 8. In this case, the base layer 8, the heat reception plate 4, and the turning tool itself are not scratched when processing. Further, it is possible to keep the length 1 from the base layer 8 to the bottom portion 77 of the groove 74 1 μm or more. The evaporation portion 7 is thus free from scratch or separation. There is no fear that the refrigerant flows through the damaged base layer 8 between the heat reception plate 4 and the base layer 8 and that the entire base layer 8 is peeled. Alternatively, the grooves 74 may be formed by press molding using a die. Also in this case, the die may be made of a material lower in hardness than the metal material constituting the base layer 8.

Alternatively, the evaporation portion 7 having the grooves 74 on the surface may be formed by causing a reactive gas to flow between a die on which desired V-shaped grooves are precisely-processed and the heat reception plate 4 provided with the base layer 8 as a catalyst layer. In this method, it is not necessary to perform cutting, so the fear of scratching the base layer 8 and the heat reception plate 4 is further decreased. Note that this method is performed only in the thermal CVD.

Alternatively, the V-shaped grooves may be formed on the heat reception plate 4, the base layer 8 as a catalyst layer having the corresponding V-shaped grooves may be formed on the heat reception plate 4, and a carbon nanotube layer having the corresponding V-shaped grooves may be formed on the base layer 8. In this method as well, it is not necessary to perform cutting, so the fear of scratching the base layer 8 and the heat reception, plate 4 is further decreased.

Next, the evaporation surface 72 is subjected to a hydrophilic processing (Step 104). In a case of using pure water as the refrigerant, the evaporation surface 72 made of carbon nanotube having hydrophobicity is subjected to a hydrophilic processing. Thus, the contact angle of the refrigerant surface with respect to the wall surface 78 of the groove 74 is decreased. By decreasing the contact angle, the thin liquid film zone of the refrigerant can be made larger. As the thin liquid film zone is larger, the more refrigerant evaporates, with the result that evaporation efficiency increases. The hydrophilic processing with respect to the evaporation surface 72 may be for example nitric acid processing for generating a carboxyl group or ultraviolet radiation. The evaporation surface 72 is subjected to a hydrophilic processing, as necessary, in accordance with a refrigerant to be used. The evaporation surface 72 may not be subjected to a hydrophilic processing in a case of not using pure water as a refrigerant.

Next, the heat reception plate 4, the sidewalls 5, and the heat radiation plate 3 are bonded liquid-tightly to form the container 2 (Step 105). In the bonding, the respective members are precisely aligned.

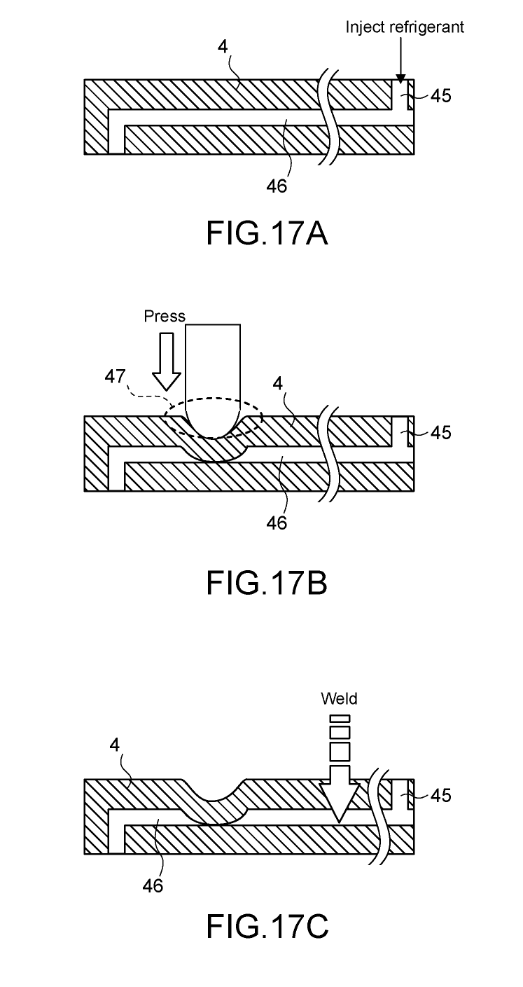

Next, the refrigerant is injected into the container 2 and the container 2 is sealed (Step 106). FIGS. 17 are schematic diagrams showing in sequence the injection method of the refrigerant into the container 2. The heat reception plate 4 includes an injection port 45 and an injection path 46.

As shown in FIG. 17A, the pressure of the flow path 6 is decreased via the injection port 45 and the injection path 46, for example, and the refrigerant is injected into the flow paths (inner flow paths) from a dispenser (not shown) via the injection port 45 and the injection path 46.

As shown in FIG. 17B, a press area 47 is pressed and the injection path 46 is closed (temporal sealing). The pressure of the flow path 6 is decreased via another injection path 46 and another injection port 45, and when the pressure of the flow path 6 reaches a target pressure, the press area 47 is pressed and the injection path 46 is closed (temporal sealing) as shown in FIG. 17B.

As shown in FIG. 17C, on a side closer to the injection port 45 than the press area 47, the injection path 46 is closed by laser welding for example (final sealing). Accordingly, the inner space of the heat spreader 1 is sealed tightly. By injecting the refrigerant into the container 2 and sealing the container 2 as described above, the heat spreader 1 is manufactured.

Next, the heat source 50 is mounted on the heat reception plate 4 (Step 107). In a case where the heat source 50 is a CPU, the process is for example a reflow soldering processing.

The reflow processing and the manufacturing processing of the heat spreader 1 may be executed at different locations (for example different factories). So, in the case of executing the injection of the refrigerant after the reflow processing, it is necessary to transport the heat spreader 1 to and from the factories, which leads to problems of cost, manpower, time, or generation of particles of the transfer between factories. According to the manufacturing method of FIG. 15, it is possible to execute the reflow processing after the completion of the heat spreader 1, solving the above problem.

According to the heat spreader manufacturing method of this embodiment, the grooves 74 are formed by processing with a turning tool, by press molding, or the like. Such processing methods are easier than cutting a substrate made of, for example, a metal material, the cost thereof is lower than the cost of the etching, and an excellent minute processability is realized. The turning tool or the die is made of a material lower in hardness than the metal material constituting the base layer 8. In this case, the base layer 8, the heat reception plate 4, and the turning tool or die itself are not scratched when processing.

Further, it is possible to keep the length 1 from the base layer 8 to the bottom portion 77 of the groove 74 1 μm or more. The evaporation portion 7 is thus free from scratch or separation. There is no fear that the refrigerant flows through the damaged base layer 8 between the heat reception plate 4 and the base layer 8 and that the entire base layer 8 is peeled. In the method of causing a reactive gas to flow or the method of forming the V-shaped grooves on the heat reception plate 4, it is not necessary to perform cutting, so the fear of scratching the base layer 8 and the heat reception plate 4 is further decreased. Thus, according to this embodiment, easier manufacture, lower cost, and higher reliability are realized.

### Second Embodiment

(Structure of Heat Spreader)

A second embodiment of the present invention will be described.

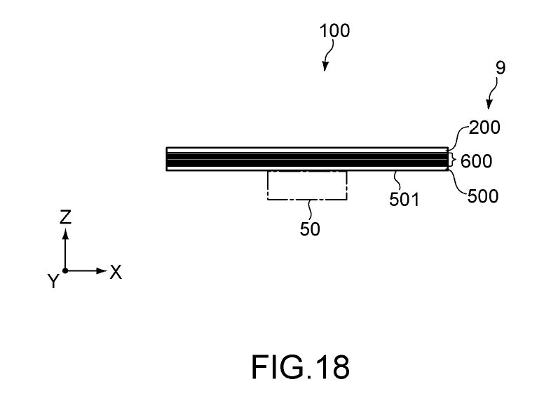

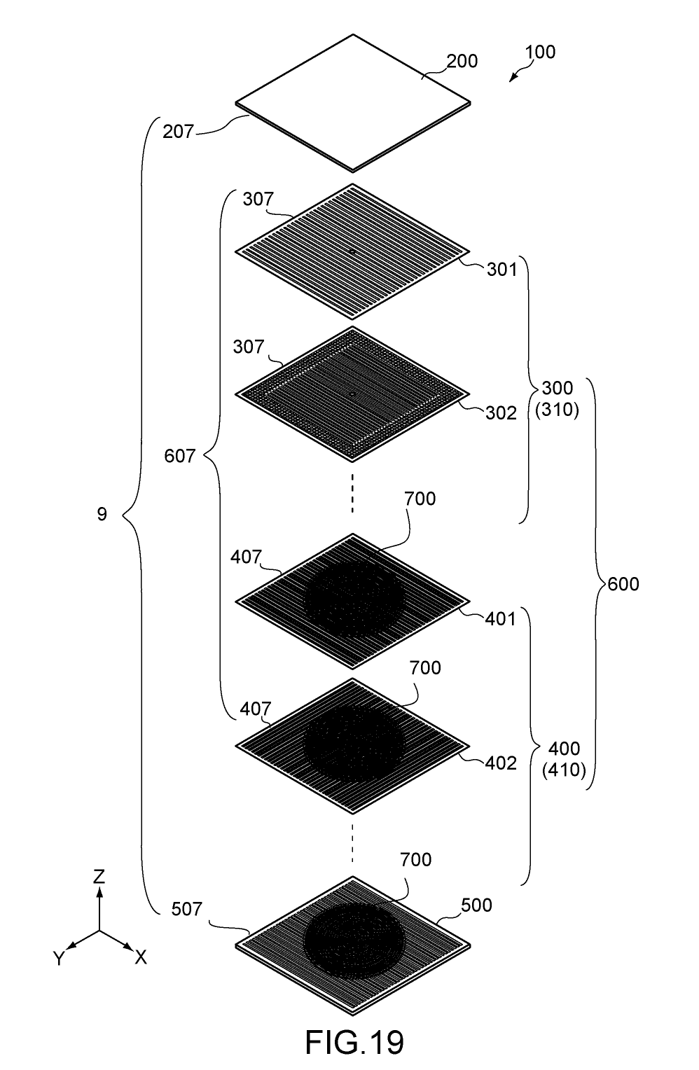

FIG. 18 is a side view showing a heat spreader of a second embodiment of the present invention, the heat spreader being thermally connected to a heat source. FIG. 19 is an exploded perspective view of the heat spreader of FIG. 18.

As shown in FIGS. 18 and 19, a heat spreader 100 includes a container 9, a plurality of flow path plate members 600, and evaporation portions 700. The heat spreader 100 further includes a refrigerant (not shown) therein. The flow path plate members 600 constitute flow paths for the refrigerant.

The container 9 further includes a heat reception plate 500, a heat radiation plate 200, and frame portions 607 of the flow path plate members 600 (described later). The heat reception plate 500 serves as a heat reception side. The heat radiation plate 200 is provided so as to face the heat reception plate 500 and serves as a heat radiation side. The heat source 50 is thermally connected to a heat reception surface 501 of the heat reception plate 500. In this embodiment also, similar to the first embodiment, the “heat reception side” may include not only the heat reception plate 500 but also a zone of the inner space of the container 9 in the vicinity of the heat reception plate 500. Similarly, the “heat radiation side” may include not only the heat radiation plate 200 but also a zone of the inner space of the container 9 in the vicinity of the heat radiation plate 200.

The plurality of flow path plate members 600 forming the flow paths are laminated between the heat reception plate 500 and the heat radiation plate 200. As shown in FIG. 19, the flow path plate members 600 include a plurality of capillary plate members 400 forming flow paths for causing, for example, the liquid refrigerant to flow with a capillary force therein. The flow path plate members 600 further include a plurality of vapor-phase plate members 300 constituting part of vapor phase flow paths mainly causing the vapor refrigerant to flow.

The evaporation portion 700 is the same as the evaporation portion 7 of the first embodiment. Specifically, the evaporation portion 700 is made of carbon nanotube, and has the V-shaped grooves 74 on the evaporation surface 72. The width a of the groove 74 desirably satisfies a≦11*2θ+50 and a≧0.3*2θ+1, where the bottom angle 20 of the groove is 10≦2θ≦130. Note that the structure, size, property, and the like of the evaporation portion 7 and the grooves 74 of the first embodiment are applied to the evaporation portion 700 of this embodiment. The evaporation portions 700 are respectively provided on the evaporation surface of the heat reception plate 500 and the surfaces of the capillary plate members 400, the surfaces facing the vapor-phase plate members 300. Specifically, the evaporation portion 700 is provided approximately in a center portion of each member, but not limited to the above. The evaporation portions 700 may be provided to all of the capillary plate members 400 or part of the capillary plate members 400.

The number of the capillary plate members 400 is for example 10 to 30, specifically 20, but not limited to 10 to 30. The number of the capillary plate members 400 may be arbitrarily changed in accordance with, for example, the amount of heat that the heat source 50 generates, the heat source 50 being thermally connected to the heat reception plate 500. The number of the vapor-phase plate members 300 is for example 1 to 20, specifically 8, but not limited to 1 to 20. The number of the vapor-phase plate members 300 may also be arbitrarily changed in accordance with, for example, the amount of heat that the heat source 50 generates.

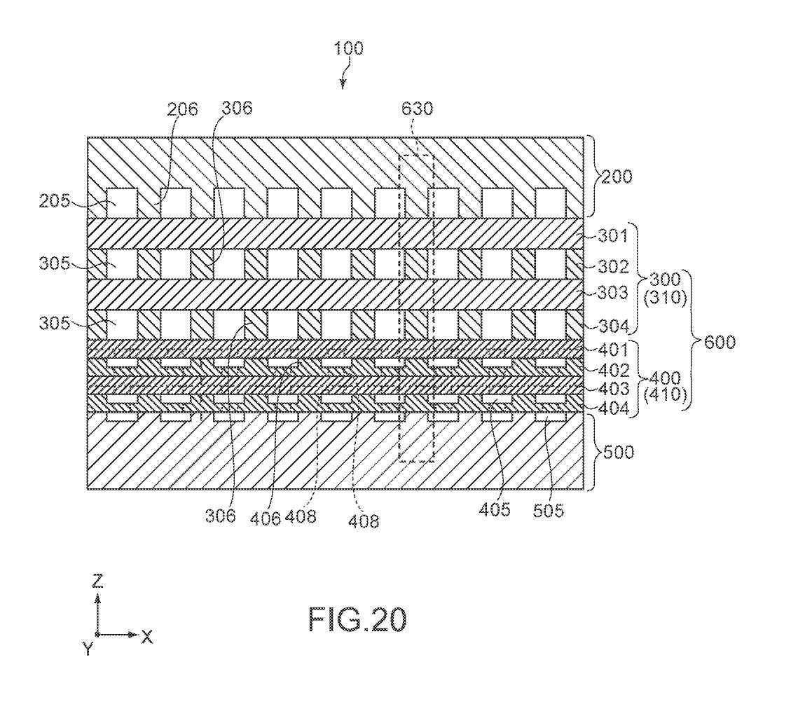

FIG. 20 is a sectional view showing part of the heat spreader 100. In FIG. 20, for easier understanding, four capillary plate members 400 (401-404) and four vapor-phase plate members 300 (301-304) are shown.

In FIG. 20, the heat reception plate 500, the plurality of capillary plate members 400 (hereinafter referred to as “capillary plate member group 410”), the plurality of vapor-phase plate members 300 (hereinafter referred to as “vapor-phase plate member group 310”), and the heat radiation plate 200 are laminated in this order from the bottom to the top. In the capillary plate member group 410, the lowest capillary plate member 404 is bonded to the heat reception plate 500. The highest capillary plate member 401 is bonded to the lowest vapor-phase plate member 304. The highest vapor-phase plate member 301 is bonded to the heat radiation plate 200.

Hereinafter, the same structural portions in the capillary plate members 401-404 will be described as the structural portion of one arbitrary capillary plate member 400, referring to as “capillary plate member 400”. Similarly, the same structural portions in the vapor-phase plate members 301-304 will be described as the structural portion of one arbitrary vapor-phase plate member 300, referring to as “vapor-phase plate member 300”.

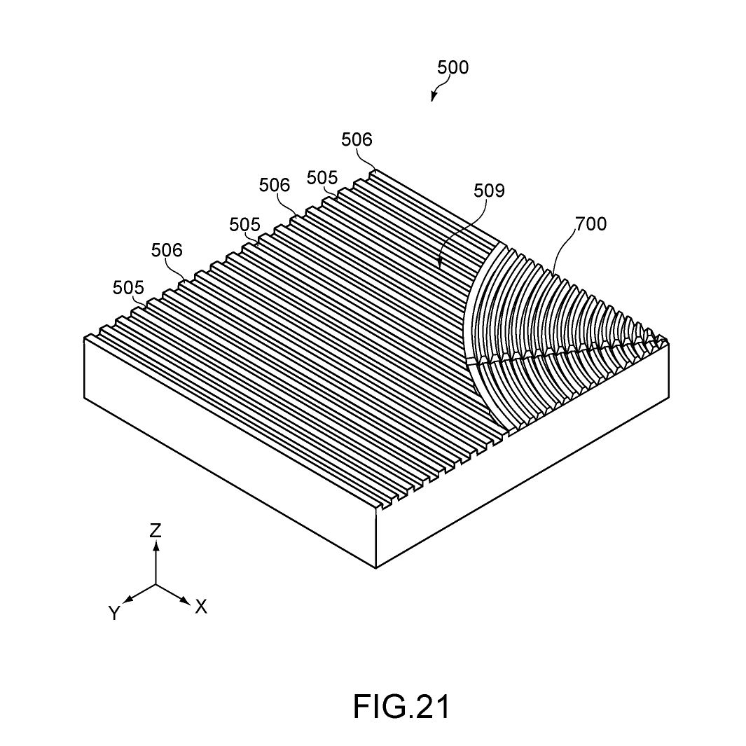

FIG. 21 is a perspective view showing an inner portion of the heat reception plate 500. In an inner portion 509 of the heat reception plate 500, a plurality of grooves 505 are formed. The depth of the groove 505 is for example 10-50 μm, specifically about 20 μm. The depth of the groove 505 is defined such that the liquid refrigerant can flow with an appropriate capillary force.

A plurality of ribs 506 are formed between the grooves 505 due to the formation of the grooves 505. The capillary plate members 400, the vapor-phase plate members 300, and the heat radiation plate 200 (described later) also have such ribs.

The shape of the groove 505 is concave in FIG. 21, but not limited to the above. The shape of the groove 505 may be an arbitrary shape such as V-shape or U-shape as long as the liquid refrigerant can flow with an appropriate capillary force. It applies to grooves 405, 205 (described later). In view of evaporation efficiency, the groove 505 may be V-shape similar to the groove 74. However, since the evaporation portion 700 provided on the heat reception plate 500 has evaporation efficiency much higher than the evaporation efficiency of the heat reception plate 500, the shape of the groove 505 may not necessarily be V-shape. Because the grooves 405, 205 (described later) are concave, in view of manufacturing efficiency, the groove 505 may also be concave.

For example, in an area on the heat reception plate 500 where the evaporation portion 700 is mounted (hereinafter referred to as “mount area”), the plurality of grooves 505 and ribs 506 are not formed. The depth of the mount area is similar to the depth of the grooves 505, and the shape of the mount area in a plan view is similar to the shape of the heat reception plate 71 in a plan view. Specifically, the thickness of the evaporation portion 700 is similar to the depth of the grooves 505. That is, the evaporation portion 700 is mounted on the mount area on the heat reception plate 500 without a gap. Specifically, the thickness of the portion of the heat reception plate 500 free from the evaporation portion 700 is similar to the thickness of the portion of the heat reception plate 500 mounted with the evaporation portion 700. The capillary plate member 400 to be described later is also formed with such a mount area mounted with the evaporation portion 700.

In the heat reception plate 500, an injection port and an injection path for the refrigerant are formed (not shown). The injection port and the injection path may be formed in the heat radiation plate 200.

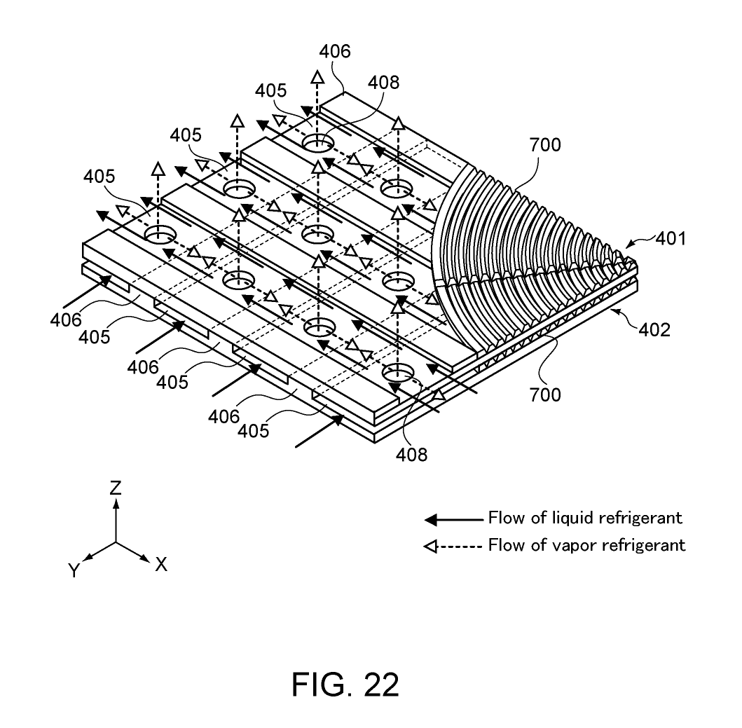

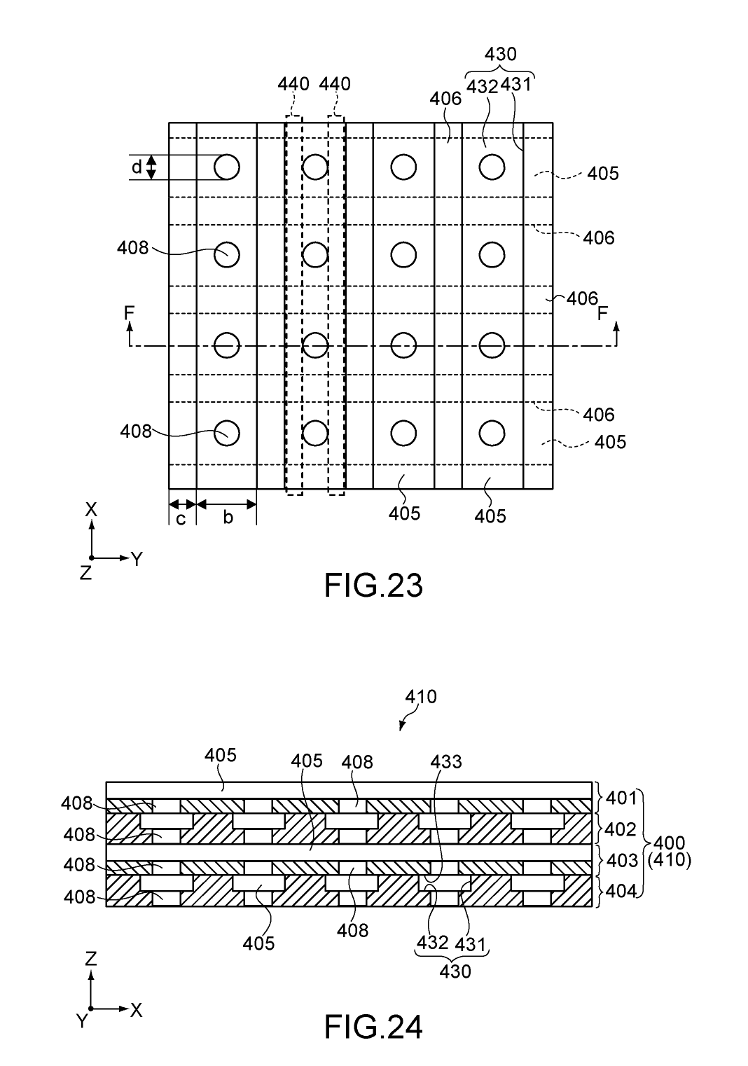

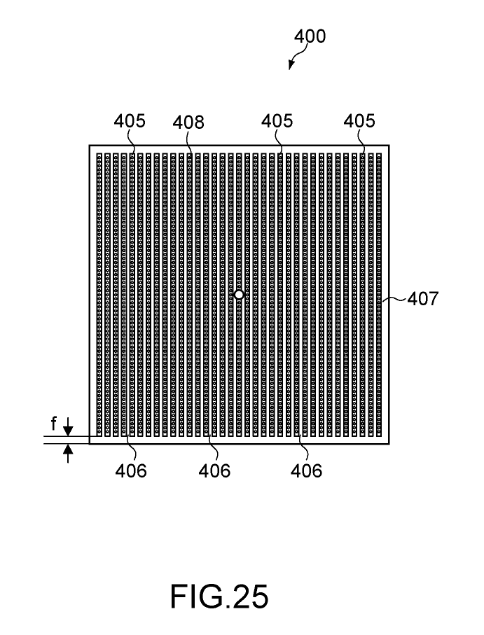

FIG. 22 is a perspective view showing part of the two laminated capillary plate members 400. FIG. 23 is a plan view showing part of the capillary plate member group 410. FIG. 24 is a sectional view showing the capillary plate member group 410 taken along the line F-F of FIG. 23. FIG. 25 is a plan view showing the entire capillary plate member 400. Each of FIGS. 23 and 24 shows a portion free from the evaporation portion 700 for easier understanding. Also, FIG. 25 shows the capillary plate member 400 having no mount area for the evaporation portion 700 for easier understanding.

On the surface of the capillary plate member 400, a plurality of grooves 405 are formed. The depth of the grooves 405 is for example about 10-50 μm, typically about 20 μm. The depth of the groove 405 is defined such that the liquid refrigerant can flow with an appropriate capillary force.

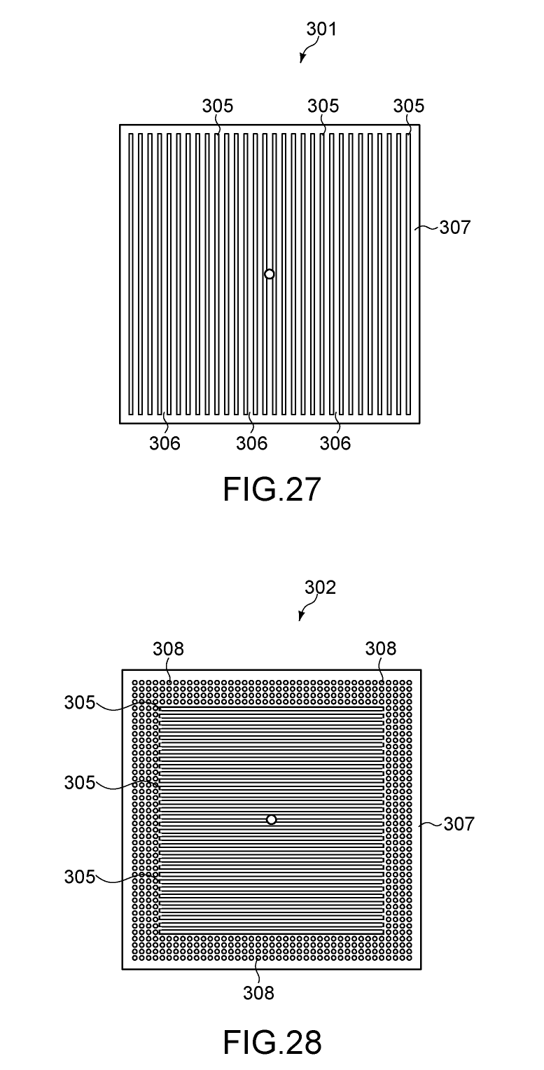

Note that in the capillary plate member 400 of FIG. 25, for easier understanding, the scale ratio of the grooves 405 and the like with respect to the entire capillary plate member 400 is made larger than the actual configuration. This applies to FIGS. 27 and 28 (described later).

The capillary plate members 401-404 are alternately turned by 90° in the XY plane and laminated such that the grooves 405 in each layer are aligned orthogonally. In a wall surface portion 430 (see FIGS. 23 and 24) forming the groove 405 of the capillary plate member 400, a plurality of openings 408 penetrating the capillary plate member 400 are formed along an elongated direction of the groove 405 (for example, X direction in FIG. 23). The wall surface portion 430 forming the groove 405 is formed by side surfaces 431 and a bottom surface 432 of the rib. The plurality of openings 408 are formed on the bottom surface 432.

For example, the capillary plate member 401 and the adjacent capillary plate member 402 will be described. The capillary plate members 401 and 402 are relatively placed and bonded such that the grooves 405 of the capillary plate member 401 communicate with the grooves 405 of the capillary plate member 402 through the openings 408 of the capillary plate member 401.

That is, the capillary plate members 401 and 402 are relatively placed and bonded such that the ribs 406 of the capillary plate member 402 do not clog the openings 408 of the capillary plate member 401, and that the lower surface of the capillary plate member 401 is bonded to the ribs 406 of the capillary plate member 402. The positional relationship of the capillary plate members 402 and 403 and the positional relationship of the capillary plate members 403 and 404 are similar to the above.

The openings 408 function as part of the vapor-phase flow path in which the vapor refrigerant flows. Note that the liquid refrigerant is heated by the heat received by the heat reception plate 500 and evaporates to be the vapor refrigerant.

The openings 408 of the capillary plate members 400 are aligned in the lamination direction (Z direction) of the flow path plate members 600. That is, the openings 408 are face to face with each other. With this structure, when the vapor refrigerant flows in the openings 408 aligned in the Z direction, smaller flow path resistance and higher thermal efficiency is realized. However, the openings 408 may not be aligned exactly in the Z direction. The openings 408 of one capillary plate member 400 may be slightly shifted in the X or Y direction from the openings 408 of the adjacent capillary plate member 400.

With reference to FIG. 24, the capillary plate member 401 and the adjacent capillary plate member 402 will be described again. The wall surface portion 430 and a ceiling surface 433 form a zone functioning as a flow path in which the liquid refrigerant mainly flows with a capillary force. The wall surface portion 430 forms the groove 405 of the capillary plate member 402. The ceiling surface 433 is the lower surface of the capillary plate member 401 and faces the bottom surface 432 of the wall surface portion 430. Note that the openings 408 are provided on the bottom surface 432 and the ceiling surface 433, and the zone extending in the Z direction formed by the openings 408 functions as a flow path for the vapor refrigerant.

Specifically, in the corners formed by the side surfaces 431 and the bottom surface 432 of the wall surface portion 430 and in the corners formed by the side surfaces 431 and the ceiling surface 433, the largest capillary force for the liquid refrigerant generates. As a result, as shown in FIG. 23, the liquid refrigerant flows in the zones 440 free from the openings 408. Note that the “wall surface portion” may include not only the side surfaces 431 and the bottom surface 432, but also the ceiling surface 433.

For example, in a case where the grooves 405 of the capillary plate member 401 function as a first flow path layer, the grooves 405 of the adjacent capillary plate member 402 function as a second flow path layer.

As shown in FIG. 23, a width b of the groove 405 is 100-200 μm. A width c of the rib 406 is 50-100 μm. A diameter d of the opening 408 is 50-100 μm. Without being limited to the above ranges, those sizes may be arbitrarily changed according to the amount of heat generated by the heat source 50 or the like.

The opening 408 is, for example, circular, but may be an arbitrary shape such as oval, elongated, or polygonal.

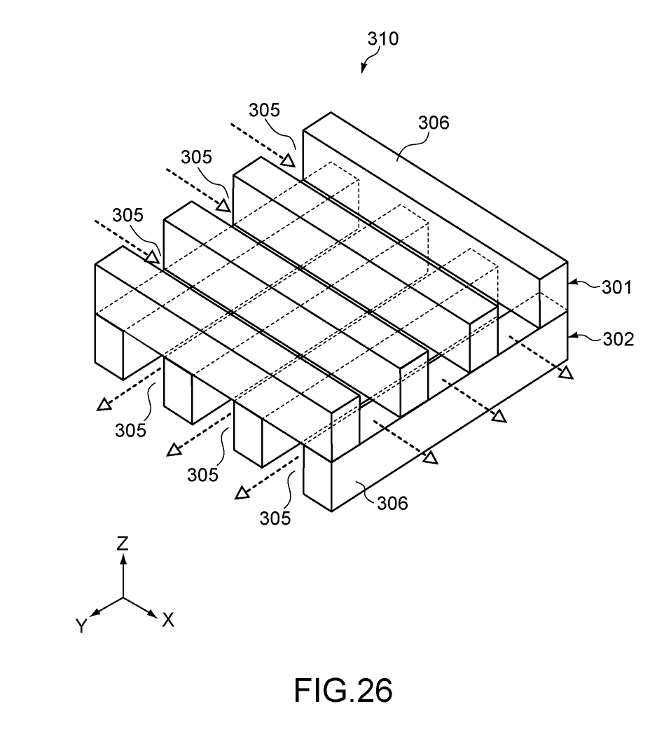

FIG. 26 is a perspective view showing part of the two laminated vapor-phase plate members 300, specifically, the vapor-phase plate members 301 and 302.

The vapor-phase plate members 300 specifically include two types of plate member. FIG. 27 is a plan view showing the entire vapor-phase plate member 301. FIG. 28 is a plan view showing the entire vapor-phase plate member 302. The vapor-phase plate members 301 and 302 commonly have a plurality of grooves 305 penetrating in the Z direction. The depth of the groove 305 is 50-150 μm, specifically about 100 μm, but not limited to the above. The depth of the groove 305 is defined such that the vapor refrigerant can flow and condense appropriately.

A plurality of ribs 306 are formed between the grooves 305 of the vapor-phase plate member 300. As shown in FIG. 26, the vapor-phase plate member 301 is turned by 90° in the XY plane with respect to the vapor-phase plate member 302 such that the grooves 305 of the vapor-phase plate member 301 are orthogonal to the grooves 305 of the vapor-phase plate member 302 adjacent to the vapor-phase plate member 301. The vapor-phase plate members 303 and 304 have the similar structural relationship. The vapor-phase plate members 301-304 are alternately turned by 90° in the XY plane.

The grooves 305 of the vapor-phase plate members 301-304 are zones in which the vapor refrigerant mainly flows. The grooves 305 function as condenser area that is part of the vapor phase flow path.

As shown in FIG. 28, the vapor-phase plate member 302 has, around the area where the grooves 305 are formed, an area where return pores 308 (return flow paths) are formed. The condensed liquid refrigerant flows in the return pores 308 to return to the grooves 405 of the capillary plate member 400. The vapor-phase plate member 301 has no return pore 308. In an adjacent area of the vapor-phase plate member 301 that corresponds to the return pores 308 of the vapor-phase plate member 302 in the Z direction, the grooves 305 are formed.

A diameter of the return pore 308 is about 50-150 μm, but may be arbitrarily changed. The diameter of the return pore 308 is defined such that the condensed liquid refrigerant can flow in the return pore 308 with an appropriate capillary force.

The vapor-phase plate member 301 having no return pore 308 and the vapor-phase plate member 302 having the return pores 308 form a pair. In this embodiment, typically, the plurality of pairs of the vapor-phase plate members are laminated. In FIG. 20, the vapor-phase plate members 301 and 303 have no return pore 308, and the vapor-phase plate members 302 and 304 have the return pores 308.

The area where the return pores 308 are formed has a width of about 5-10 mm, but the width may be arbitrarily changed.

Alternatively, the plurality of vapor-phase plate members 301 having no return pore 308 may only be laminated to form the vapor-phase plate member group 310. The plurality of vapor-phase plate members 302 having the return pores 308 may only be laminated to form the vapor-phase plate member group 310. The vapor-phase plate members 300 closer to the heat radiation plate 200 may be the plurality of vapor-phase plate members 301 having no return pore 308, and the vapor-phase plate members 300 closer to the capillary plate members 400 may be the plurality of vapor-phase plate members 302 having the return pores 308. The plurality of vapor-phase plate members 301 and 302 may be laminated in a random order.

For example, in a case where the grooves 305 of the vapor-phase plate member 302 function as a first flow path layer, the grooves 305 of the adjacent vapor-phase plate members 302 function as a second flow path layer.

As shown in FIG. 20, the heat radiation plate 200 has the plurality of grooves 205 on an inner side as in the case of the heat reception plate 500. The groove 205 has functions and a size similar to those of the groove 305 of the vapor-phase plate member 300. The heat reception plate 500, the capillary plate member group 410, the vapor-phase plate member group 310, and the heat radiation plate 200 are laminated such that the ribs 506 of the heat reception plate 500, the ribs 406 of the capillary plate member group 410, the ribs 306 of the vapor-phase plate member group 310, and the ribs 206 of the heat radiation plate 200 form column structures (for example, a portion surrounded by a dashed square 630 of FIG. 20) in the Z direction. A plurality of column structures 630 are thus formed. The heat reception plate 500, the capillary plate member group 410, and the evaporation portions 700 also form column structures. With the column structures, the heat spreader 100 can ensure enough strength to bear compression stress applied to the heat spreader 100 from the outside.

The heat reception plate 500, the capillary plate member group 410, the vapor-phase plate member group 310, the heat radiation plate 200, and the evaporation portions 700 are diffusion-bonded. With the diffusion bonding, the heat spreader 100 can ensure enough strength to bear tensile stress generated in the heat spreader 100 as will be described later.

The grooves 505, 405, 305, and 205, the openings 408, the injection path, and the like structured as described above are specifically formed by the MEMS (Micro Electro Mechanical Systems) technique such as the photolithography technique, the etching technique, or the like. Alternatively, they may be formed by other processing methods such as laser processing.

As shown in FIGS. 19, 25, 27, and 28, the heat reception plate 500 has a frame portion 507 free from the grooves 505. The flow path plate members 600 have the frame portions 607 free from the grooves 305 and 405. That is, the vapor-phase plate members 300 have frame portions 307 and the capillary plate members 400 have frame portions 407. The heat radiation plate 200 has a frame portion 207 free from the grooves 205. The frame portions 507, 407, 307, and 207 are bonded. Accordingly, the heat reception plate 500, the heat radiation plate 200, and the frame portions 307 and 407 form the container 9 of the heat spreader 100.

As shown in FIG. 25, for example, a width f of the frame portion 407 is a few mm, but may be arbitrarily changed. The frame portions 507, 307, and 207 have a width f similar to the width f of the frame portion 407. The width f of the frame portions 507, 407, 307, and 207 is defined appropriately in accordance with the strength of the container, the ratio of the flow paths in the XY plane of the heat spreader 100, the amount of heat generated by the heat source 50, or the like.

The heat reception plate 500, the plurality of flow path plate members 600, and the heat radiation plate 200 may be bonded by brazing, that is, welded, or may be bonded with an adhesive material depending on the materials. Alternatively, they may be bonded by the diffusion bonding described above. The plurality of capillary plate members 400 may be bonded as described above. The plurality of vapor-phase plate members 300 may be bonded as described above. The heat reception plate 500, the plurality of capillary plate members 400, and the evaporation portions 700 may be bonded as described above.

(Operation of Heat Spreader)

The operation of the heat spreader 100 as structured above will be described.

When the heat source 50 generates heat, the heat reception plate 500 receives the heat. Then, the liquid refrigerant flows with a capillary force in the grooves 405 of the capillary plate member group 410 and the grooves 74 of the evaporation portion 700. The liquid refrigerant evaporates from the capillary plate member group 410 and the evaporation portion 700 to be the vapor refrigerant. Some of the vapor refrigerant flows in the grooves 405 and 74, but most of the vapor refrigerant flows in the openings 408 toward the heat radiation plate 200 side and in the grooves 305 of the vapor-phase plate member group 310. As the vapor refrigerant flows in the grooves 305 of the vapor-phase plate member group 310, the heat diffuses, and the vapor refrigerant condenses to be the liquid phase. Thus the heat spreader 100 radiates the heat mainly from the heat radiation plate 200. The liquid refrigerant flows in the return pores 308 to return to the grooves 405 of the capillary plate member group 410 and the grooves 74 of the evaporation portion 700 by the capillary force. By repeating the above operation, the heat spreader 100 transports the heat of the heat source 50.

Based on the premise that the liquid refrigerant and the vapor refrigerant mix in the flow paths, the heat spreader 100 of this embodiment is devised by controlling the flow directions of the liquid refrigerant and the vapor refrigerant.

That is, the liquid refrigerant flows in the plurality of grooves 405 and 74 in the XY directions. The vapor refrigerant flows in the openings 408 having the smaller flow path resistance in the Z direction. Because no opening is provided in the evaporation portion 700, the liquid refrigerant is positively and actively caused to flow in the grooves 74 and to evaporate. The liquid refrigerant flowing in the grooves 405 mainly concentrate on the side surfaces 431 of the wall surface portions 430, with the result that the vapor refrigerant does not hinder the flow of the liquid refrigerant. Accordingly, thermal efficiency due to the phase transition can be increased and heat resistance can be decreased.

### Third Embodiment

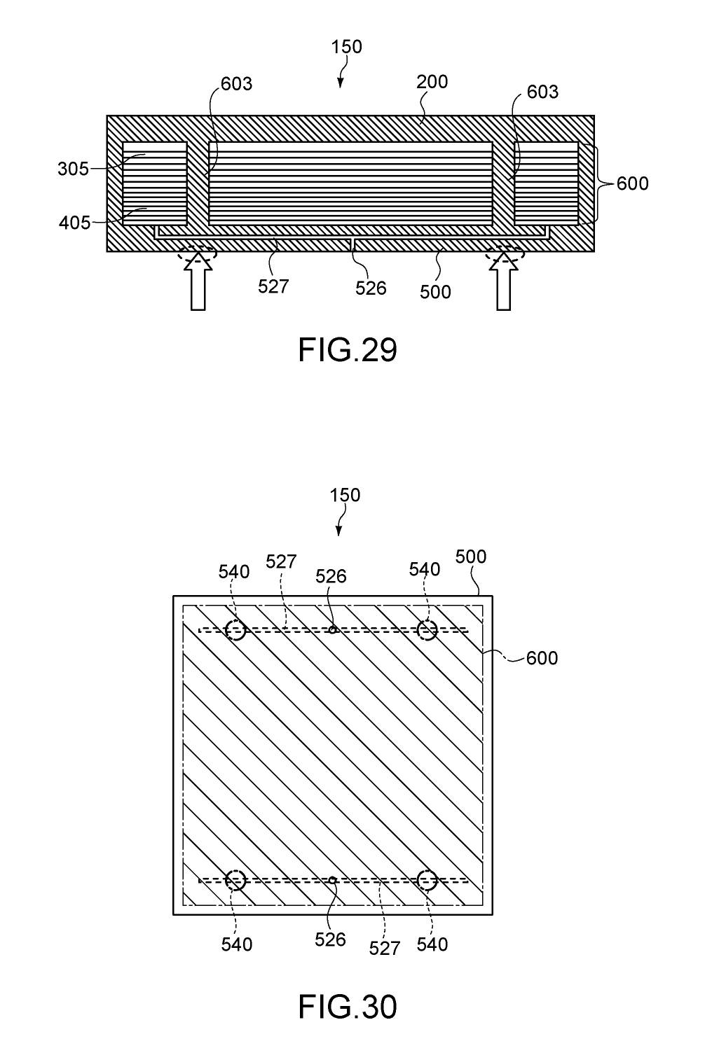

FIG. 29 is a schematic sectional view showing a heat spreader 150 according to a third embodiment of the present invention. FIG. 30 is a plan view showing the heat spreader 150 of FIG. 29.

In the heat spreader 150, the heat reception plate 500 includes, for example, two injection ports 526 for the refrigerant and injection paths 527 communicating with the injection ports 526, respectively. The heat reception plate 500 may be made of two plate members. Grooves (as the injection paths 527) and openings (as the injection ports 526) are formed in one of the two plate members, and then the two plate members are bonded. The heat reception plate 500 having the injection paths 527 and the injection ports 526 is thus formed. The injection paths 527 communicate with the grooves 405 of the capillary plate members 400. Alternatively, one injection path 527 and one injection port 526 may be formed. Note that the hatched portion of FIG. 30 is the portion in which the flow paths for the refrigerant are formed in the flow path plate members 600.

The injection path 527 is linear, for example, and predetermined portions of the linear injection path 527 serve as press areas 540, which are pressed to clog the injection path 527. The press areas 540 are, in other words, swage areas. In the zones corresponding to the swage areas of the heat spreader 150, column portions 603 are formed between the heat reception plate 500 and the heat radiation plate 200 in the Z direction. That is, the column portions 603 are formed in the flow path plate members 600.

In the ribs of the heat reception plate 500, the capillary plate members 400, the vapor-phase plate members 300, and the heat radiation plate 200, column-shaped portions are formed. When the heat reception plate 500, the capillary plate members 400, the vapor-phase plate members 300, and the heat radiation plate 200 are laminated, the column-shaped portions are aligned in the Z direction. The column portions 603 are thus formed. A width (diameter) of the column portion 603 is arbitrarily defined such that the flow paths (inner flow paths) formed by the flow path plate members 600 are not clogged with the pressure force when swaging.

The injection method of the refrigerant into the heat spreader 150 is similar to the method of FIG. 17.

By providing the column portions 603 at the positions corresponding to the press areas 540, the inner flow paths are not clogged with the pressure force when swaging.

The heat spreader 150 may be formed such that the inner flow paths are not formed in the zone corresponding to the injection path 527. In this case, the dedicated press areas 540 may be formed in the zone free from the inner flow paths. However, in the case where the dedicated press areas 540 are formed in the zone free from the inner flow paths, the zone corresponding to the dedicated press areas 540 have lower heat diffusion function.

In the heat spreader 150 of this embodiment, the inner flow paths are provided in the vicinity of the column portions 603. Accordingly, in the substantially entire surface of the heat spreader 150, the higher heat diffusion efficiency is realized.

(Manufacturing Method of Heat Spreader)

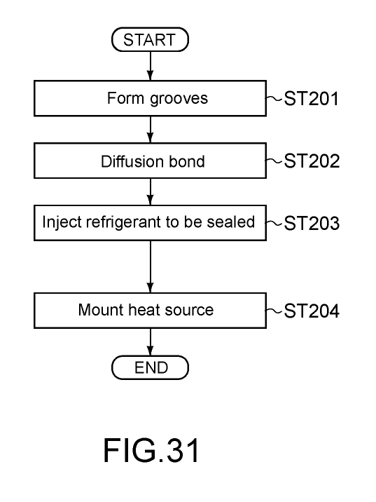

A manufacturing method of the heat spreader 150 (heat spreader 100) of an embodiment of the present invention will be described. FIG. 31 is a flowchart showing the manufacturing method.

A plurality of plate members are prepared. The grooves 505, 405, 305, and 205, the openings 408, and the like are formed on the plate members (Step 201). The heat reception plate 500, the plurality of flow path plate members 600, and the heat radiation plate 200 are thus formed.

The evaporation portions 700 are mounted on the mount areas of the heat reception plate 500 and the capillary plate members 400. The heat reception plate 500, the capillary plate members 400, the vapor-phase plate members 300, and the heat radiation plate 200 are laminated such that the plurality of flow path plate members 600 are sandwiched by the heat reception plate 500 and the heat radiation plate 200. Those plate members are diffusion-bonded (Step 202). In laminating, the respective plate members are precisely aligned. In the diffusion bonding, metal binding occurs. The strength or stiffness of the heat spreader 150 is thus improved.

As shown in FIGS. 17A-17C, the refrigerant is injected into the inner flow paths, and the container is sealed (Step 203). The heat spreader 150 is thus manufactured.

Next, the heat source 50 is mounted on the heat reception plate 500 (Step 204). In a case where the heat source 50 is mounted on the heat reception plate 500 by, for example, a reflow soldering processing, the temperature of the heat reception plate 500 and the entire heat spreader 150 increases up to about 230-240° C. In this environment, the refrigerant evaporates to increase the inner pressure. However, because the plate members are diffusion-bonded (Step 202), the heat spreader 150 can ensure enough strength or stiffness to bear tensile stress due to the inner pressure.

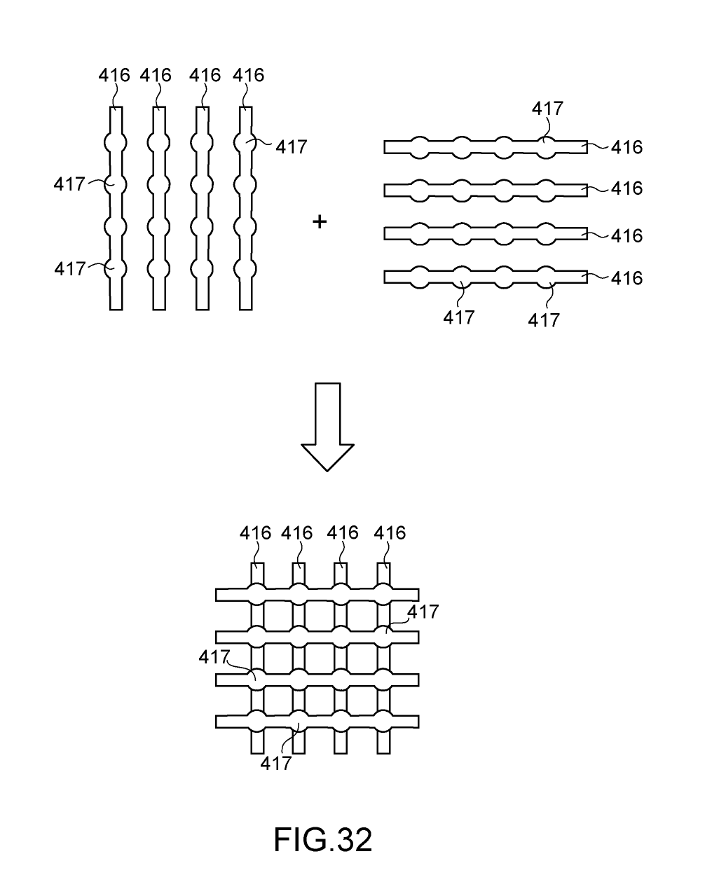

FIG. 32 is a schematic view showing ribs of the heat spreader 100 or 150 according to another embodiment of the present invention. In FIG. 32, the ribs 416 of the plurality of capillary plate members 400 have a plurality of column portions 417. The pitch, number, size, or the like of the plurality of column portions 417 may arbitrarily be defined. Other than the column shape, the column portions 417 may be oval, rectangular, or the like.

The plurality of capillary plate members 400 are bonded such that the column portions 417 of the plurality of capillary plate members 400 are aligned in the Z direction to be bonded. The heat reception plate 500 and the capillary plate members 400 may be bonded as described above. The capillary plate members 400 and the vapor-phase plate members 300 may be bonded as described above. The vapor-phase plate members 300 and the heat radiation plate 200 may be bonded as described above.

With this structure, the total bond area can be increased without affecting the inner flow paths and the heat spreader 150 can ensure increased strength or stiffness with respect to the compression stress from the outside and the inner tensile stress.

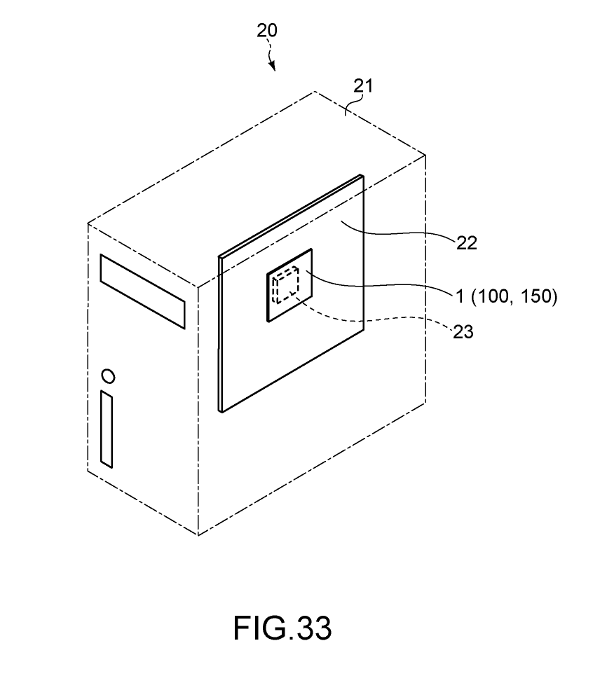

FIG. 33 is a perspective view showing a desktop PC as an electronic apparatus including the heat spreader 1 (100, 150). In a case 21 of a PC 20, a circuit board 22 is provided, and a CPU 23 for example is mounted on the circuit board 22. The CPU 23 as a heat source is thermally connected to the heat spreader 1 (100, 150). The heat spreader 1 (100, 150) is thermally connected to a heat sink (not shown).

It should be understood by those skilled in the art that various modifications, combinations, sub-combinations, and alterations may occur depending on design requirements and other factors insofar as they are within the scope of the appended claims or the equivalents thereof.

The shape of the heat spreader 1 (100, 150) is rectangular or square in a plan view. However, the shape in a plan view may be circular, oval, polygonal, or another arbitrary shape.

The shapes of the grooves 74, 505, 405, 305, and 205, the wall surface portions 430, the ribs 506, 406, 306, and 206, the frame portions 507, 407, 307, and 207, and the like may arbitrarily be changed.

As an electronic apparatus, a desktop PC of FIG. 33 is exemplarily shown. However, not limited to the above, as an electronic apparatus, a PDA (Personal Digital Assistance), an electronic dictionary, a camera, a display apparatus, an audio/visual apparatus, a projector, a mobile phone, a game apparatus, a car navigation apparatus, a robot apparatus, a laser generation apparatus, or another electronic appliance may be employed.

The present application contains subject matter related to that disclosed in Japanese Priority Patent Application JP 2008-296626 filed in the Japan Patent Office on Nov. 20, 2008, the entire content of which is hereby incorporated by reference.

What is claimed is:

1. A heat transport device, comprising:
an evaporation portion made of nanomaterial, the evaporation portion having V-shaped grooves formed on a surface;
a flow path to communicate with the evaporation portion;
a condenser portion to communicate with the evaporation portion through the flow path; and
a working fluid to evaporate from a liquid phase to a vapor phase in the evaporation portion and condense from the vapor phase to the liquid phase in the condenser portion.

2. The heat transport device according to claim 1,
wherein each of the V-shaped grooves has a bottom angle 2θ (10≦2θ≦130) and a width a, a relationship of the bottom angle 2θ (10≦2θ≦130) and the width a being a≦11*2θ+50 and a≧0.3*2θ+1.

3. The heat transport device according to claim 1,
wherein the V-shaped grooves are provided on the surface of the evaporation portion in a concentric manner and in a radial manner.

4. The heat transport device according to claim 1,
wherein the V-shaped grooves are provided on the surface of the evaporation portion in a spiral manner and in a radial manner.

5. The heat transport device according to claim 1,
wherein a distance between a back surface of the evaporation portion and a bottom portion of each of the V-shaped grooves is 1 μm or more.

6. The heat transport device according to claim 1,
wherein the surface of the evaporation portion has hydrophilicity.

7. An electronic apparatus, comprising:
a heat source; and
a heat transport device thermally connected to the heat source, the heat transport device including an evaporation portion made of nanomaterial, the evaporation portion having V-shaped grooves formed on a surface, a flow path to communicate with the evaporation portion, a condenser portion to communicate with the evaporation portion through the flow path, and a working fluid to evaporate from a liquid phase to a vapor phase in the evaporation portion and condense from the vapor phase to the liquid phase in the condenser portion.

8. A heat transport device manufacturing method, comprising:
forming a catalyst layer on a substrate constituting an evaporation portion;
forming a nanomaterial layer on the catalyst layer; and
forming V-shaped grooves on the nanomaterial layer by one of turning tool processing and press molding.

9. The heat transport device manufacturing method according to claim 8,
wherein the V-shaped grooves are formed on the nanomaterial layer such that a distance between the catalyst layer and a bottom portion of each of the V-shaped grooves is 1 μm or more.

10. The heat transport device manufacturing method according to claim 8, further comprising
subjecting a surface of the nanomaterial layer to a hydrophilic processing.

11. A heat transport device manufacturing method, comprising:
forming a catalyst layer on a substrate constituting an evaporation portion; and
causing a reactive gas to flow between the substrate provided with the catalyst layer and a die to form a nanomaterial layer having V-shaped grooves on a surface.

12. The heat transport device manufacturing method according to claim 11, further comprising
subjecting a surface of the nanomaterial layer to a hydrophilic processing.

13. A heat transport device manufacturing method, comprising:
forming V-shaped grooves on a substrate constituting an evaporation portion;
forming a catalyst layer on the substrate; and
forming a nanomaterial layer on the catalyst layer.

14. The heat transport device manufacturing method according to claim 13, further comprising
subjecting a surface of the nanomaterial layer to a hydrophilic processing.
